(19) United States
(12) Patent Application Publication
(10) Pub. No.: US 2024/0155856 A1
(43) Pub. Date: May 9, 2024

(54) IMAGING DEVICE

(71) Applicant: Panasonic Intellectual Property Management Co., Ltd., Osaka (JP)

(72) Inventor: YOSHIHIRO SATO, Osaka (JP)

(21) Appl. No.: 18/412,683

(22) Filed: Jan. 15, 2024

Related U.S. Application Data
(63) Continuation of application No. PCT/JP2022/027345, filed on Jul. 12, 2022.

(30) Foreign Application Priority Data
Aug. 5, 2021 (JP) 2021-129386

(51) Int. Cl. H10K 39/32

(52) U.S. Cl. CPC H10K 39/32

(57) ABSTRACT

An imaging device includes a semiconductor substrate, an impurity region, a first transistor, and a second transistor. The impurity region is located in a semiconductor substrate. The impurity region holds electric charge generated through photoelectric conversion. The first transistor includes a first source, a first drain, a first gate, and a first gate-insulating film. One of the first source and the first drain includes the impurity region. The first gate is electrically connected to the impurity region. The first gate-insulating film is located between the first gate and the semiconductor substrate. The second transistor includes a second gate and a second gate-insulating film. The second gate is electrically connected to the impurity region. The second gate-insulating film is located between the second gate and the semiconductor substrate. The thickness of the first gate-insulating film is greater than the thickness of the second gate-insulating film.

### BACKGROUND

### 1. Technical Field

The present disclosure relates to an imaging device.

### 2. Description of the Related Art

Charge-coupled device (CCD) image sensors and complementary metal oxide semiconductor (CMOS) image sensors are used in digital cameras and the like. An image sensor according to an example includes a photodiode provided on a semiconductor substrate.

For example, WO 2014/002330 and WO 2012/147302 disclose a structure in which a photoelectric converter is located above a semiconductor substrate. An imaging device having such a structure is called a stacking-type imaging device in some cases. In the stacking-type imaging device, electric charge generated through photoelectric conversion is accumulated in charge storage capacitance. A signal in accordance with the amount of electric charge accumulated in the charge storage capacitance is read through a CCD circuit or CMOS circuit provided on a semiconductor substrate. The charge storage capacitance is also referred to as a floating diffusion (FD) capacitance.

### SUMMARY

In one general aspect, the techniques disclosed here feature an imaging device including: a semiconductor substrate; an impurity region that is located in the semiconductor substrate and that holds electric charge generated through photoelectric conversion; a first transistor including a first source, a first drain, a first gate, and a first gate-insulating film, one of the first source and the first drain including the impurity region, the first gate being electrically connected to the impurity region, the first gate-insulating film being located between the first gate and the semiconductor substrate; and a second transistor including a second gate and a second gate-insulating film, the second gate being electrically connected to the impurity region, the second gate-insulating film being located between the second gate and the semiconductor substrate. The thickness of the first gate-insulating film is greater than the thickness of the second gate-insulating film.

A comprehensive or specific aspect may be achieved as an element, a device, a module, a system, or a method. A comprehensive or specific aspect may be achieved by optional combination of an element, a device, a module, a system, and a method.

Additional benefits and advantages of the disclosed embodiments will become apparent from the specification and drawings. The benefits and/or advantages may be individually obtained by the various embodiments and features of the specifications and drawings, which need not all be provided in order to obtain one or more of such benefits and/or advantages.

### BRIEF DESCRIPTION OF THE DRAWINGS

FIG. 1 is a configuration diagram of an imaging device according to Embodiment 1;

FIG. 2 is a diagram illustrating a circuit configuration of the imaging device according to Embodiment 1;

FIG. 3A is a plan view illustrating arrangement in a pixel in Embodiment 1;

FIG. 3B is a plan view illustrating a relatively thick part and a relatively thin part of an insulating layer;

FIG. 4 is a schematic sectional view of a device structure of a pixel in Embodiment 1;

FIG. 5A is an explanatory diagram of the length and width of a gate;

FIG. 5B is an explanatory diagram of the length and width of the gate;

FIG. 5C is an explanatory diagram of the length and width of the gate;

FIG. 6 is a diagram for description of the perimeter length of the gate;

FIG. 7 is a schematic sectional view of a device structure of a pixel in Embodiment 2;

FIG. 8 is a diagram illustrating a circuit configuration in Embodiment 3;

FIG. 9 is a plan view illustrating arrangement in a pixel in Embodiment 3;

FIG. 10 is a diagram illustrating a circuit configuration in Embodiment 4;

FIG. 11 is a plan view illustrating arrangement in a pixel in Embodiment 4;

FIG. 12A is a diagram illustrating a circuit configuration in Embodiment 5;

FIG. 12B is a diagram illustrating a circuit configuration in a modification of Embodiment 5;

FIG. 13 is a plan view illustrating arrangement in a pixel in Embodiment 5;

FIG. 14 is a diagram illustrating a circuit configuration in Embodiment 6;

FIG. 15 is a plan view illustrating arrangement in a pixel in Embodiment 6;

FIG. 16 is a diagram illustrating a circuit configuration in Embodiment 7;

FIG. 17 is a plan view illustrating arrangement in a pixel in Embodiment 7;

FIG. 18 is a diagram illustrating a circuit example including a photodiode;

FIG. 19 is a diagram illustrating a circuit example including a photodiode;

FIG. 20 is a diagram illustrating a circuit example including a photodiode;

FIG. 21 is a diagram illustrating a circuit example including a photodiode; and

FIG. 22 is a diagram illustrating a circuit example including a photodiode.

### DETAILED DESCRIPTIONS

### Summary of One Aspect According to Present Disclosure

An imaging device according to a first aspect of the present disclosure includes:
a semiconductor substrate;
an impurity region that is located in the semiconductor substrate and that holds electric charge generated through photoelectric conversion;
a first transistor including a first source, a first drain, a first gate, and a first gate-insulating film, one of the first source and the first drain including the impurity region, the first gate being electrically connected to the impurity region, the first gate-insulating film being located between the first gate and the semiconductor substrate; and
a second transistor including a second gate and a second gate-insulating film, the second gate being electrically connected to the impurity region, the second gate-insulating film being located between the second gate and the semiconductor substrate.

The thickness of the first gate-insulating film is greater than the thickness of the second gate-insulating film.

The technology according to the first aspect is suitable for achieving an imaging device having high image quality.

In a second aspect of the present disclosure, for example, the imaging device according to the first aspect may further include
a photoelectric converter that is located above the semiconductor substrate and that generates the electric charge through photoelectric conversion.

The configuration according to the second aspect is a specific example of the configuration of the imaging device.

In a third aspect of the present disclosure, for example, the imaging device according to the first aspect or the second aspect may further include
a third transistor including a third source, a third drain, a third gate, and a third gate-insulating film, one of the third source and the third drain including the impurity region, the third gate-insulating film being located between the third gate and the semiconductor substrate.

The configuration according to the third aspect is a specific example of the configuration of the imaging device.

In a fourth aspect of the present disclosure, for example, in the imaging device according to the third aspect,
the thickness of the third gate-insulating film may be greater than the thickness of the second gate-insulating film.

The technology according to the fourth aspect is suitable for achieving an imaging device having high image quality.

In a fifth aspect of the present disclosure, for example, in the imaging device according to any one of the first to fourth aspects,
the width of the first gate may be less than the width of the second gate.

The technology according to the fifth aspect is suitable for achieving an imaging device having high image quality.

In a sixth aspect of the present disclosure, for example, in the imaging device according to any one of the first to fifth aspects,
the area of the first gate may be less than the area of the second gate in a plan view.

The technology according to the sixth aspect is suitable for achieving an imaging device having high image quality.

In a seventh aspect of the present disclosure, for example, in the imaging device according to any one of the first to sixth aspects,
the ratio of the length of the first gate relative to the width of the first gate may be greater than the ratio of the length of the second gate relative to the width of the second gate.

The technology according to the seventh aspect is suitable for achieving an imaging device having high image quality.

In an eighth aspect of the present disclosure, for example, the imaging device according to any one of the first to seventh aspects may further include
an insulating layer,
the insulating layer may include a first part and a second part, the first part including the first gate-insulating film, the second part including the second gate-insulating film,
the thickness of the first part may be greater than the thickness of the second part, and
when the shortest line segment connecting the first gate and the second gate in a plan view is defined as a specific line segment and the middle point of the specific line segment is defined as a specific point, the specific point may be located on the first part in the plan view.

The technology according to the eighth aspect is suitable for achieving an imaging device having high image quality.

In a ninth aspect of the present disclosure, for example, the imaging device according to any one of the first to eighth aspects may further include:
an insulating layer; and
a wire electrically connected to the first gate,
the insulating layer may include a first part and a second part, the first part including the first gate-insulating film, the second part including the second gate-insulating film,
the thickness of the first part may be greater than the thickness of the second part, and
when a region in which the semiconductor substrate, the first part, and the wire are arranged in the stated order in a thickness direction of the semiconductor substrate is defined as a specific region, the specific region may extend from inside of the first gate to outside of the first gate in a plan view.

The technology according to the ninth aspect is suitable for achieving an imaging device having high image quality.

In a tenth aspect of the present disclosure, for example, in the imaging device according to any one of the first to ninth aspects,
the second transistor may be an amplification transistor.

The configuration according to the tenth aspect is a specific example of the configuration of the imaging device.

In an eleventh aspect of the present disclosure, for example, in the imaging device according to the third aspect,
the thickness of the first gate-insulating film may be greater than the thickness of the third gate-insulating film.

In a twelfth aspect of the present disclosure, for example, in the imaging device according to the third aspect,
the thickness of the second gate-insulating film may be equal to the thickness of the third gate-insulating film.

In a thirteenth aspect of the present disclosure, for example, in the imaging device according to the second aspect,
the photoelectric converter may be constantly electrically connected to the impurity region.

In a fourteenth aspect of the present disclosure, for example, in the imaging device according to the second aspect,
no switch element may be located between the photoelectric converter and the impurity region.

An imaging device according to a fifteenth aspect of the present disclosure includes:
a semiconductor substrate;
an impurity region that is located in the semiconductor substrate and that holds electric charge generated through photoelectric conversion;
a first transistor including a first source, a first drain, a first gate, and a first gate-insulating film, one of the first source and the first drain including the impurity region, the first gate-insulating film being located between the first gate and the semiconductor substrate;
a capacitive element electrically connected to the other of the first source and the first drain; and
a second transistor including a second gate and a second gate-insulating film, the second gate being electrically connected to the impurity region, the second gate-insulating film being located between the second gate and the semiconductor substrate,
the thickness of the first gate-insulating film is greater than the thickness of the second gate-insulating film.

The technology according to the fifteenth aspect is suitable for achieving an imaging device having high image quality.

In a sixteenth aspect of the present disclosure, for example, in the imaging device according to the fifteenth aspect, the second transistor may be turned on in accordance with a potential change in the impurity region.

The configuration according to the sixteenth aspect is a specific example of the configuration of the imaging device. The sixteenth aspect includes an aspect in which the second transistor is turned on when a control signal is supplied to the gate of the second transistor in accordance with potential change in the impurity region. The sixteenth aspect also includes an aspect in which the second transistor is automatically turned on in accordance with a potential change in the impurity region without supply of the control signal.

In a seventeenth aspect of the present disclosure, for example, the imaging device according to the fifteenth aspect or the sixteenth aspect may further include a third transistor that resets the potential of the impurity region.

The configuration according to the seventeenth aspect is a specific example of the configuration of the imaging device.

In an eighteenth aspect of the present disclosure, for example, the imaging device according to any one of the fifteenth to seventeenth aspects may further include:
a fourth transistor including a fourth source, a fourth drain, a fourth gate, and a fourth gate-insulating film, one of the fourth source and the fourth drain including the impurity region, the fourth gate-insulating film being located between the fourth gate and the semiconductor substrate; and
a photoelectric converter that generates the electric charge through photoelectric conversion, and
whether the impurity region is electrically connected to the photoelectric converter may be switched in accordance with whether the fourth transistor is turned on or off.

The configuration according to the eighteenth aspect is a specific example of the configuration of the imaging device.

An imaging device according to a nineteenth aspect of the present disclosure includes:
a semiconductor substrate;
an impurity region that is located in the semiconductor substrate and that holds electric charge generated through photoelectric conversion;
a first transistor including a first source, a first drain, a first gate, and a first gate-insulating film, one of the first source and the first drain including the impurity region, the first gate being electrically connected to the other of the first source and the first drain, the first gate-insulating film being located between the first gate and the semiconductor substrate; and
a second transistor including a second gate and a second gate-insulating film, the second gate being electrically connected to the impurity region, the second gate-insulating film being located between the second gate and the semiconductor substrate, and
the thickness of the first gate-insulating film is greater than the thickness of the second gate-insulating film.

The technology according to the nineteenth aspect is suitable for achieving an imaging device having high image quality.

The technologies of the first to nineteenth aspects may be optionally combined without inconsistency.

Embodiments of the present disclosure will be described below in detail with reference to the accompanying drawings. Each embodiment described below provides a comprehensive or specific example. Numerical values, shapes, constituent components, disposition positions and connection aspects of constituent components, steps, the order of steps, and the like described in the embodiments below are exemplary and not intended to limit the present disclosure. Various kinds of aspects described in the present specification may be combined with each other without inconsistency. Among constituent components in the embodiments below, any constituent component not written in an independent claim indicating the highest-level concept is described as an optional constituent component. In the drawings, constituent components having essentially identical functions are denoted by the reference sign, and duplicate description thereof is omitted or simplified in some cases.

Various elements in the drawings are schematically illustrated to understand the present disclosure, and for example, the dimensional ratios and appearances thereof may be different from those in reality.

In each embodiment, the light-receiving side of an imaging device is defined as an “upper side”, and the side opposite the light-receiving side is defined as a “lower side”. Similarly, as for an “upper surface” and a “lower surface” of each member, the “upper surface” is defined to be a surface facing the light-receiving side of the imaging device, and the “lower surface” is defined to be a surface facing the side opposite the light-receiving side. Terms such as “upper side”, “lower side”, “upper surface”, and “lower surface” are merely used to designate the mutual disposition of members and are not intended to limit the posture of the imaging device when used.

In each embodiment, the term “leakage current” is used in some cases. Leakage current is also referred to as dark current.

In each embodiment, a “plan view” is a view in the thickness direction of a semiconductor substrate.

In each embodiment, an “n-type impurity region” is a region containing n-type impurities. A “p-type impurity region” is a region containing p-type impurities.

In each embodiment, the polarities of transistors and the conduction types of impurity regions are examples. The polarities of transistors and the conduction types of impurity regions may be inverted without inconsistency.

In each embodiment, “connection” may be interpreted as “electrical connection” without inconsistency. In each embodiment, a “gate” may be interpreted as a “gate electrode” without inconsistency.

### Embodiment 1

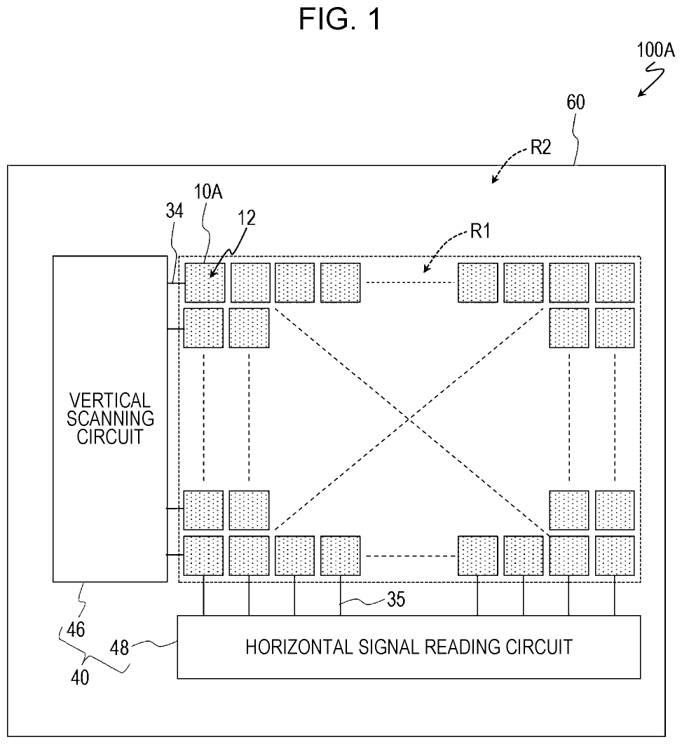

FIG. 1 is a configuration diagram of an imaging device 100A according to Embodiment 1. The imaging device 100A includes a plurality of pixels 10A and peripheral circuits 40 provided on a semiconductor substrate 60. The imaging device 100A includes a photoelectric converter 12. The photoelectric converter 12 is located above the semiconductor substrate 60 and generates electric charge through photoelectric conversion. The stacking-type imaging device 100A will be described below as an example of an imaging device according to the present disclosure. Specifically, each pixel 10A includes the photoelectric converter 12.

In the example illustrated in FIG. 1, the pixels 10A are located in a matrix of m rows and n columns. The numbers m and n are integers of two or greater. The pixels 10A are, for example, two-dimensionally arrayed on the semiconductor substrate 60 to constitute an imaging region R1. As described above, each pixel 10A includes the photoelectric converter 12 located above the semiconductor substrate 60. The imaging region R1 is defined as a region covered by the photoelectric converters 12 on the semiconductor substrate 60. The photoelectric converters 12 of the pixels 10A are spatially separated from each other in the illustration of FIG. 1 to facilitate description. However, the photoelectric converters 12 of the plurality of pixels 10A may be located on the semiconductor substrate 60 without a gap from each other.

The number and disposition of pixels 10A are not limited to the illustrated example. Although the centers of the pixels 10A are located on lattice points of a square lattice in the example, the pixels 10A may be differently located. For example, the plurality of pixels 10A may be located such that their centers are located on lattice points of a triangular lattice, a hexagonal lattice, or the like. The imaging device 100A can be used as a line sensor in a case in which the pixels 10A are one-dimensionally arrayed. The number of pixels 10A included in the imaging device 100A may be plural or one.

In the configuration exemplarily illustrated in FIG. 1, the peripheral circuits 40 include a vertical scanning circuit 46 and a horizontal signal reading circuit 48. The vertical scanning circuit 46 is connected to address signal lines 34 provided corresponding to respective rows of the plurality of pixels 10A. The horizontal signal reading circuit 48 is connected to vertical signal lines 35 provided corresponding to respective columns of the plurality of pixels 10A. As schematically illustrated in FIG. 1, these circuits are located in a peripheral region R2 outside the imaging region R1. The vertical scanning circuit 46 is also referred to as a row scanning circuit. The horizontal signal reading circuit 48 is also referred to as a column scanning circuit.

The peripheral circuits 40 may additionally include a signal processing circuit, an output circuit, a control circuit, a power source, or the like. The power source supplies, for example, a predetermined voltage to each pixel 10A. Some of the peripheral circuits 40 may be located on another substrate different from the semiconductor substrate 60 whereas the pixels 10A are provided on the semiconductor substrate 60.

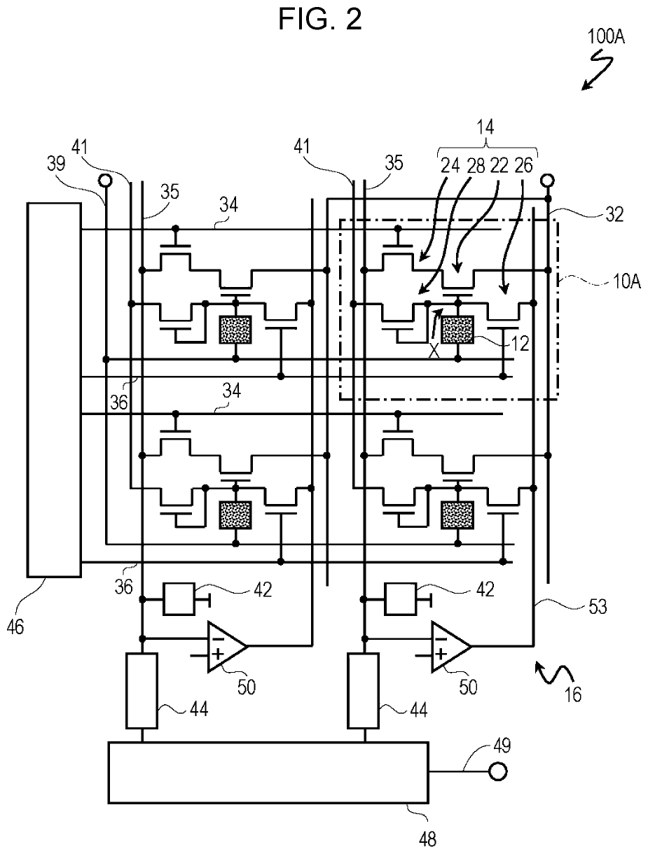

FIG. 2 is a diagram illustrating a circuit configuration of the imaging device 100A according to Embodiment 1. To avoid the complication of the drawing, FIG. 2 only illustrates four pixels 10A arrayed on two rows and two columns among the plurality of pixels 10A illustrated in FIG. 1.

The photoelectric converter 12 of each pixel 10A receives incident light and generates positive and negative electric charges. The positive and negative electric charges are typically hole-electron pairs. The photoelectric converter 12 of each pixel 10A is connected to an accumulation control line 39, and a predetermined voltage is applied to the accumulation control line 39 when the imaging device 100A is in operation. Upon application of the predetermined voltage to the accumulation control line 39, One of the positive and negative electric charges generated through photoelectric conversion can be selectively accumulated in charge storage capacitance. The following description will be made on an example in which positive electric charge among positive and negative electric charges generated through photoelectric conversion is used as signal electric charge.

The charge storage capacitance will be described below. The charge storage capacitance means the whole capacitance that holds signal electric charge generated through photoelectric conversion. The whole capacitance that holds signal electric charge means a structure actually exerting a function to hold signal electric charge. The charge storage capacitance is also referred to as a floating diffusion (FD) capacitance.

In the present embodiment, the charge storage capacitance includes an impurity region X provided on the semiconductor substrate 60, and an element electrically connected to the impurity region X. Specifically, in the present embodiment, the charge storage capacitance includes a pixel electrode 12a of the photoelectric converter 12, a gate 22e of an amplification transistor 22, and a gate 28e of a seizure prevention transistor 28, and the impurity region X. The charge storage capacitance also includes a wiring structure 80 electrically connecting the pixel electrode 12a, the gate 22e, the gate 28e, and the impurity region X. In the present embodiment, the impurity region X is one of the source and drain of the seizure prevention transistor 28 and one of the source and drain of a reset transistor 26.

Each pixel 10A includes a signal detection circuit 14 connected to the corresponding photoelectric converter 12. In the configuration exemplarily illustrated in FIG. 2, the signal detection circuit 14 includes the amplification transistor 22, the reset transistor 26, an address transistor 24, and the seizure prevention transistor 28. The amplification transistor 22 is also referred to as a reading transistor or a source-follower transistor. The address transistor 24 is also referred to as a row selection transistor.

As described later in detail with reference to the accompanying drawings, the amplification transistor 22, the reset transistor 26, the seizure prevention transistor 28, and the address transistor 24 of the signal detection circuit 14 are typically field effect transistors (FETs). These field effect transistors are provided on the semiconductor substrate 60 that supports the photoelectric converter 12.

Unless otherwise stated, the following description will be made on an example in which N-channel metal oxide semiconductor (MOS) FETs are used as transistors. Which of the two diffusion layers of an FET is a source or a drain is determined based on the polarity of the FET and the magnitude of potential at that time point. Thus, which of the two diffusion layers is a source or a drain varies depending on the actuation state of the FET.

As schematically illustrated in FIG. 2, the gate of the amplification transistor 22 is electrically connected to the photoelectric converter 12. The drain of the amplification transistor 22 is electrically connected to a power source wire 32 through which predetermined power voltage VDD is supplied to each pixel 10A when the imaging device 100A is in operation. The power voltage VDD is, for example, 3.3 V approximately. The power source wire 32 is also referred to as a source-follower power source. The amplification transistor 22 outputs signal voltage in accordance with the amount of signal electric charge generated by the photoelectric converter 12. The source of the amplification transistor 22 is electrically connected to the drain of the address transistor 24.

Consider a case in which no seizure prevention transistor 28 is provided. In this case, when excessive light is incident on the photoelectric converter 12, electric charge is excessively accumulated in the charge storage capacitance and the potential of the charge storage capacitance potentially exceeds VDD. However, in the present embodiment, the seizure prevention transistor 28 is provided. The seizure prevention transistor 28 is set to have such threshold voltage that, for example, the transistor is turned on when the potential of the charge storage capacitance becomes equal to VDD. In this manner, excessive electric charge can be discharged from the charge storage capacitance to a power source line 41. As a result, failure such as seizure can be prevented. The threshold voltage means the voltage between the gate and source of the transistor when the drain current starts flowing to the transistor.

A vertical signal line 35 is electrically connected to the source of the address transistor 24. As illustrated, each vertical signal line 35 is provided for a column of the plurality of pixels 10A and connected to a load circuit 42 and a column signal processing circuit 44. The load circuit 42 constitutes a source-follower circuit together with the amplification transistor 22. The column signal processing circuit 44 is also referred to as a row signal accumulation circuit.

An address signal line 34 is electrically connected to the gate of the address transistor 24. Each address signal line 34 is provided for a row of the plurality of pixels 10A. The vertical scanning circuit 46 is connected to each address signal line 34 and applies, to the address signal line 34, a row selection signal that controls whether the address transistor 24 is turned on or off. Accordingly, a reading target row is selected through scanning in a vertical direction. In the illustrated example, the vertical direction is the column direction. The vertical scanning circuit 46 can read output from the amplification transistor 22 of a selected pixel 10A onto the corresponding vertical signal line 35 by controlling whether the address transistor 24 is turned on or off through the address signal line 34. Disposition of the address transistor 24 is not limited to the example illustrated in FIG. 2 but may be between the drain of the amplification transistor 22 and the power source wire 32.

The signal voltage from the pixel 10A is output to the vertical signal line 35 through the address transistor 24. Thereafter, the signal voltage is input to a corresponding column signal processing circuit 44 among the plurality of column signal processing circuits 44 provided for respective columns of the plurality of pixels 10A and corresponding to the vertical signal lines 35. The column signal processing circuits 44 and the load circuits 42 may be part of the above-described peripheral circuits 40.

Each column signal processing circuit 44 performs noise suppression signal processing, analog-digital conversion (AD conversion), and the like. The noise suppression signal processing is, for example, correlated double sampling. The column signal processing circuit 44 is connected to the horizontal signal reading circuit 48. The horizontal signal reading circuit 48 sequentially reads signals from the plurality of column signal processing circuits 44 to a horizontal common signal line 49.

In the configuration exemplarily illustrated in FIG. 2, each signal detection circuit 14 includes the reset transistor 26. The drain of the reset transistor 26 is the impurity region X. In the illustrated example, the impurity region X is shared by the seizure prevention transistor 28 and the reset transistor 26. A reset signal line 36 connected to the vertical scanning circuit 46 is electrically connected to the gate of the reset transistor 26. The reset signal lines 36 are provided for respective rows of the plurality of pixels 10A like the address signal lines 34.

The vertical scanning circuit 46 can select a row of reset target pixels 10A by applying the row selection signal to the corresponding address signal line 34. The vertical scanning circuit 46 also can turn on each reset transistor 26 on the selected row by applying a reset signal that controls whether the reset transistor 26 is turned on or off to the gate of the reset transistor 26 through the corresponding reset signal line 36. The potential of the corresponding charge storage capacitance is reset when the reset transistor 26 is turned on.

In this example, the source of each reset transistor 26 is electrically connected to one of feedback lines 53 provided for respective columns of the plurality of pixels 10A. In other words, in this example, the voltage of the feedback line 53 is supplied to the corresponding charge storage capacitances as reset voltage that initializes the electric charge of the corresponding photoelectric converters 12. Each above-described feedback line 53 is electrically connected to an output terminal of a corresponding one of inverting amplifiers 50 provided for respective columns of the plurality of pixels 10A. The inverting amplifiers 50 may be part of the above-described peripheral circuits 40.

Consider one column of the plurality of pixels 10A. As illustrated, the corresponding inverting amplifier 50 has an inverting input terminal electrically connected to the vertical signal line 35 of the column. The inverting amplifier 50 has an output terminal electrically connected to one or more pixels 10A belonging to the column through the corresponding feedback line 53. When the imaging device 100A is in operation, predetermined voltage Vref is supplied to a non-inverting input terminal of the inverting amplifier 50. The voltage Vref is, for example, 1 V or positive voltage in the vicinity of 1 V. One of the one or more pixels 10A belonging to the column is selected and the corresponding address transistors 24 and the corresponding reset transistors 26 are turned on to constitute a feedback path for negative feedback of output from the pixel 10A. Through the feedback path, the voltage of the vertical signal line 35 converges to the input voltage Vref to the non-inverting input terminal of the inverting amplifier 50. In other words, through the feedback path, the voltage of each corresponding charge storage capacitance is reset to voltage with which the voltage of the vertical signal line 35 becomes equal to Vref. The voltage Vref may be voltage with an optional magnitude in the range of power voltage and ground voltage. The power voltage is, for example, 3.3 V. The ground voltage is 0 V. Each inverting amplifier 50 may be referred to as a feedback amplifier. In this manner, the imaging device 100A has a feedback circuit 16 including each inverting amplifier 50 as part of the feedback path.

As is well known, thermal noise called kTC noise is generated when a transistor is turned on or off. Noise generated when a reset transistor is turned on or off is called reset noise. Reset noise generated when a reset transistor is turned off after the potential of charge storage capacitance is reset remains in the charge storage capacitance in which signal electric charge is to be accumulated. However, reset noise generated when a reset transistor is turned off can be reduced by utilizing feedback. Details of the reset noise reduction by utilizing feedback are disclosed in WO 2012/147302. The entire disclosed contents of WO 2012/147302 are incorporated in the present specification by reference.

In the configuration exemplarily illustrated in FIG. 2, an alternating-current component of thermal noise is fed back to the source of each reset transistor 26 through the corresponding feedback path. Since the feedback path is held until right before the reset transistor 26 is turned off in the configuration exemplarily illustrated in FIG. 2, reset noise generated when the reset transistor 26 is turned off can be reduced.

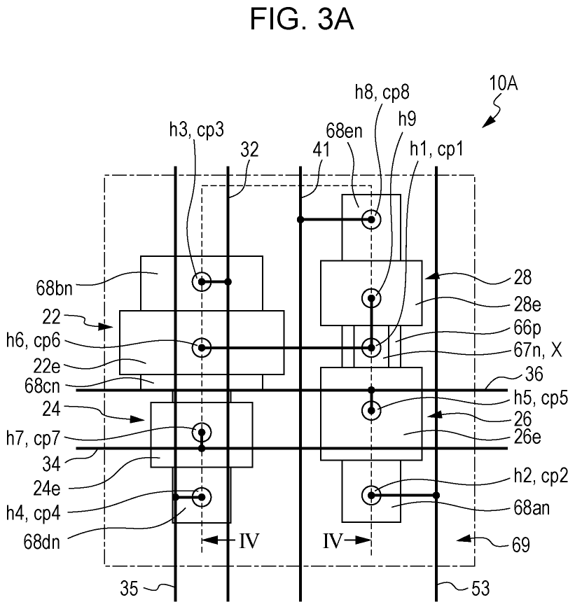

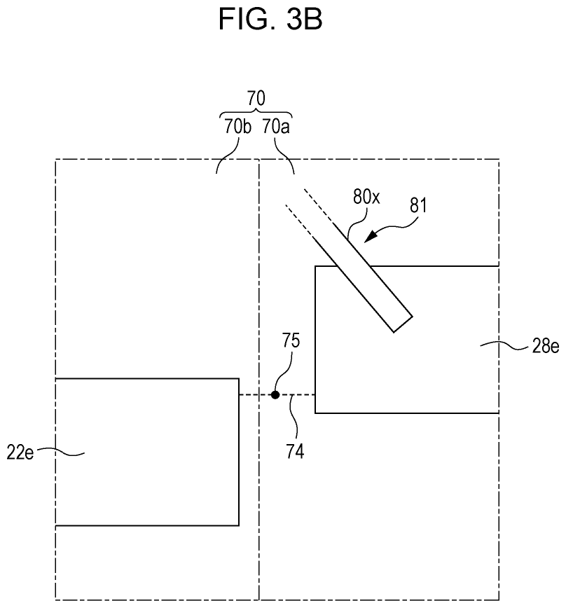

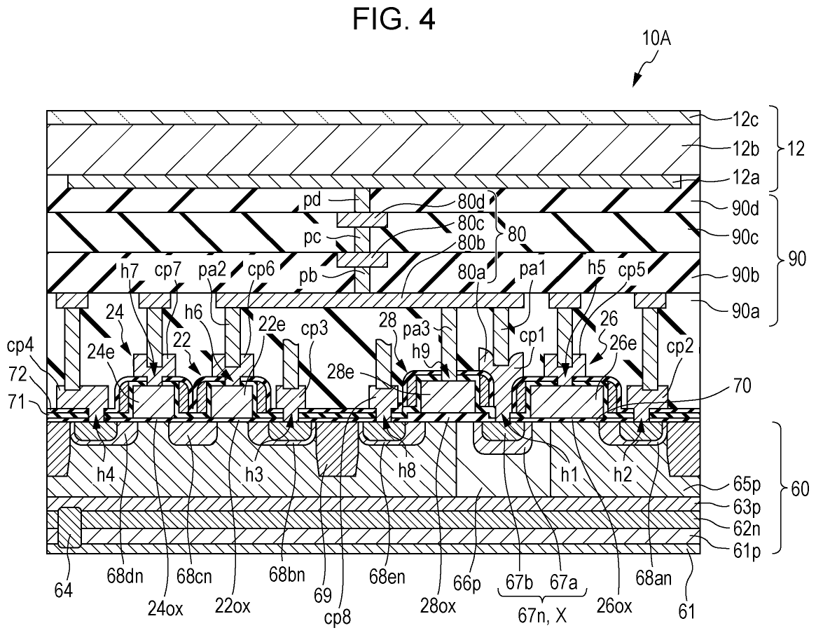

FIG. 3A is a plan view illustrating the arrangement in each pixel 10A in Embodiment 1. FIG. 3B is a plan view illustrating a relatively thick part and a relatively thin part of an insulating layer 70. FIG. 4 is a sectional view schematically illustrating a device structure in each pixel in Embodiment 1. Specifically, FIG. 4 is a schematic sectional view of a device structure of each pixel 10A when cut along line IV-IV in FIG. 3A and viewed in the arrow directions. FIG. 3A schematically illustrates the disposition of elements provided on the semiconductor substrate 60 in a plan view of each pixel 10A illustrated in FIG. 2. These elements are the amplification transistor 22, the address transistor 24, the seizure prevention transistor 28, the reset transistor 26, and the like. In the example of FIG. 3A, the amplification transistor 22 and the address transistor 24 are located straight in the up-down direction of the sheet.

N-type impurity regions 67n, 68an, 68bn, 68cn, 68dn, and 68en are provided in the semiconductor substrate 60. The n-type impurity region 67n is the impurity region X.

As illustrated in FIGS. 3A and 4, the pixel 10A in the imaging device 100A according to the present embodiment includes the reset transistor 26. The reset transistor 26 includes the n-type impurity region 67n as one of its source and drain and includes the n-type impurity region 68an as the other. The n-type impurity region 67n accumulates photoelectric charge converted by the corresponding photoelectric converter 12.

In addition, the pixel 10A includes the amplification transistor 22 and the address transistor 24. The amplification transistor 22 includes the n-type impurity region 68bn as one of its source and drain and includes the n-type impurity region 68cn as the other. The address transistor 24 includes the n-type impurity region 68cn as one of its source and drain and includes the n-type impurity region 68dn as the other.

In the present embodiment, the n-type impurity concentration of the n-type impurity region 67n is less than the n-type impurity concentrations of the n-type impurity regions 68an, 68bn, 68cn, and 68dn. For example, the n-type impurity concentration of the n-type impurity region 67n is less than 1/10 of the n-type impurity concentrations of the n-type impurity regions 68an, 68bn, 68cn, and 68dn. Accordingly, junction concentration at a junction part between the n-type impurity region 67n and the semiconductor substrate 60 is small, and thus electric field intensity at the junction part is decreased. Thus, leakage current from the n-type impurity region 67n as an electric charge accumulation region or leakage current to the n-type impurity region 67n is reduced.

In addition, pixel 10A includes the seizure prevention transistor 28. The seizure prevention transistor 28 includes the gate 28e, a source, and a drain. The n-type impurity region 67n functions as one of the source and drain of the seizure prevention transistor 28. The n-type impurity region 68en functions as the other of the source and drain of the seizure prevention transistor 28. The n-type impurity region 67n also functions as one of the source and drain of the reset transistor 26. In this manner, the n-type impurity region 67n is shared between the above-described two transistors.

The n-type impurity concentration of the n-type impurity region 67n may be less than the n-type impurity concentration of the n-type impurity region 68en. Specifically, the n-type impurity concentration of the n-type impurity region 67n may be less than the n-type impurity concentrations of the other n-type impurity regions 68an to 68en in pixel 10A. With this configuration, the junction concentration of the n-type impurity region 67n and the semiconductor substrate 60 decreases and thus leakage current can be reduced.

In the imaging device 100A according to the present embodiment, the semiconductor substrate 60 contains p-type impurities. The concentration of n-type impurities contained in the n-type impurity region 67n and the concentration of p-type impurities contained in the semiconductor substrate 60 may be higher than or equal to 1×10¹⁶ atoms/cm³ and lower than or equal to 5×10¹⁶ atoms/cm³. Accordingly, the junction concentration of the n-type impurity region 67n and the semiconductor substrate 60 decreases, and the increase of electric field intensity at the junction part can be reduced. Thus, the leakage current at the junction part can be reduced.

As schematically illustrated in FIG. 4, the pixel 10A mainly includes the semiconductor substrate 60, the photoelectric converter 12, and the wiring structure 80. The photoelectric converter 12 is located above the semiconductor substrate 60. An interlayer insulating layer 90 is formed between the photoelectric converter 12 and the semiconductor substrate 60. The wiring structure 80 is located in the interlayer insulating layer 90. The wiring structure 80 electrically connects the amplification transistor 22 and the photoelectric converter 12 provided on the semiconductor substrate 60.

In the illustrated example, the interlayer insulating layer 90 has a stacking structure. The stacking structure includes insulating layers 90a, 90b, 90c, and 90d. The wiring structure 80 includes wiring layers 80a, 80b, 80c, and 80d (hereinafter referred to as the wiring layers 80a to 80d). The wiring structure 80 includes plugs pa1, pa2, pa3, pb, pc, and pd located in the wiring layers 80a to 80d. The wiring layer 80a includes contact plugs cp1, cp2, cp3, cp4, cp5, cp6, cp7, and cp8 (hereinafter referred to as the contact plugs cp1 to cp8). The number of insulating layers in the interlayer insulating layer 90 and the number of wiring layers in the wiring structure 80 are not limited to the example but may be optionally set.

The photoelectric converter 12 is located on the interlayer insulating layer 90. The photoelectric converter 12 includes the pixel electrode 12a, a transparent electrode 12c, and a photoelectric conversion layer 12b. The pixel electrode 12a is provided on the interlayer insulating layer 90. The transparent electrode 12c faces the pixel electrode 12a. The photoelectric conversion layer 12b is located between the pixel electrode 12a and the transparent electrode 12c.

The photoelectric conversion layer 12b receives light incident through the transparent electrode 12c and generates positive and negative electric charges through photoelectric conversion. The photoelectric conversion layer 12b is typically provided across the plurality of pixels 10A. The photoelectric conversion layer 12b is made of an organic material or an inorganic material. The inorganic material is, for example, amorphous silicon. The photoelectric conversion layer 12b may include a layer made of an organic material and a layer made of an inorganic material.

The transparent electrode 12c is located on a light-receiving surface side of the photoelectric conversion layer 12b. The transparent electrode 12c is made of a transparent conductive material. The conductive material is, for example, indium tin oxide (ITO). Similarly to the photoelectric conversion layer 12b, the transparent electrode 12c is typically provided across the plurality of pixels 10A. Although not illustrated in FIG. 4, the transparent electrode 12c is connected to the above-described accumulation control line 39. When the imaging device 100A is in operation, the signal electric charge generated through photoelectric conversion can be collected by the pixel electrode 12a by differentiating the potential of the transparent electrode 12c and the potential of the pixel electrode 12a through control of the potential of the accumulation control line 39. For example, the potential of the accumulation control line 39 is controlled so that the potential of the transparent electrode 12c becomes higher than the potential of the pixel electrode 12a. Specifically, for example, a positive voltage of 10 V approximately is applied to the accumulation control line 39. Accordingly, holes in hole-electron pairs generated in the photoelectric conversion layer 12b can be collected by the pixel electrode 12a. The signal electric charge collected by the pixel electrode 12a is accumulated in the n-type impurity region 67n through the wiring structure 80.

The pixel electrode 12a is spatially separated from the pixel electrode 12a of any other adjacent pixel 10A. Accordingly, the pixel electrode 12a is electrically separated from the pixel electrode 12a of any other pixel 10A. The pixel electrode 12a is an electrode made of metal, metallic nitride, polysilicon, or the like. The metal is, for example, aluminum or copper. The polysilicon has conductivity through doping with impurities, for example.

The semiconductor substrate 60 includes a support substrate 61 and one or more semiconductor layers. One or more semiconductor layers are provided on the support substrate 61. The support substrate 61 is, for example, a p-type silicon (Si) substrate. In this example, the semiconductor substrate 60 includes an n-type semiconductor layer 62n, a p-type semiconductor layer 61p, a p-type semiconductor layer 63p, and a p-type semiconductor layer 65p. The p-type semiconductor layer 61p is located on the support substrate 61. The n-type semiconductor layer 62n is located on the p-type semiconductor layer 61p. The p-type semiconductor layer 63p is located on the n-type semiconductor layer 62n. The p-type semiconductor layer 65p is located on the p-type semiconductor layer 63p.

The p-type semiconductor layer 63p is provided across the entire surface of the support substrate 61. A p-type impurity region 66p, the n-type impurity region 67n, the n-type impurity regions 68an and 68en, and an element separation region 69 are provided in the p-type semiconductor layer 65p. The impurity concentration of the p-type impurity region 66p is lower than the impurity concentration of the p-type semiconductor layer 65p. The n-type impurity region 67n is formed in the p-type impurity region 66p.

The p-type semiconductor layer 61p, the n-type semiconductor layer 62n, the p-type semiconductor layer 63p, and the p-type semiconductor layer 65p are each typically formed through ion injection of impurities into a semiconductor layer formed by epitaxial growth. The impurity concentration of the p-type semiconductor layer 65p is equivalent to the impurity concentration of the p-type semiconductor layer 63p. This impurity concentration is higher than the impurity concentration of the p-type semiconductor layer 61p. The n-type semiconductor layer 62n located between the p-type semiconductor layer 61p and the p-type semiconductor layer 63p prevents the flow of minority carriers from the support substrate 61 or the peripheral circuits 40 into the n-type impurity region 67n in which signal electric charge is accumulated. When the imaging device 100A is in operation, the potential of the n-type semiconductor layer 62n is controlled through a well contact provided outside the imaging region R1 illustrated in FIG. 1. Illustration of the well contact is omitted.

In this example, the semiconductor substrate 60 includes a p-type region 64. The p-type region 64 is provided between the p-type semiconductor layer 63p and the support substrate 61, penetrating through the p-type semiconductor layer 61p and the n-type semiconductor layer 62n. The p-type region 64 has an impurity concentration higher than those of the p-type semiconductor layer 63p and the p-type semiconductor layer 65p. The p-type region 64 electrically connects the p-type semiconductor layer 63p and the support substrate 61. When the imaging device 100A is in operation, the potentials of the p-type semiconductor layer 63p and the support substrate 61 are controlled through a substrate contact provided outside the imaging region R1. An illustration of the substrate contact is omitted. Since the p-type semiconductor layer 65p is located in contact with the p-type semiconductor layer 63p, the potential of the p-type semiconductor layer 65p can be controlled through the p-type semiconductor layer 63p when the imaging device 100A is in operation.

The reset transistor 26, the seizure prevention transistor 28, the amplification transistor 22, and the address transistor 24 are provided on the semiconductor substrate 60.

The reset transistor 26 includes the n-type impurity regions 67n and 68an, part of the insulating layer 70 provided on the semiconductor substrate 60, and a gate 26e on the insulating layer 70. The n-type impurity region 67n functions as the drain of the reset transistor 26. The n-type impurity region 68an functions as the source of the reset transistor 26. The part of the insulating layer 70 functions as a gate-insulating film 26ox of the reset transistor 26. The n-type impurity region 67n temporarily accumulates signal electric charge generated by the photoelectric converter 12.

The seizure prevention transistor 28 includes the n-type impurity regions 67n and 68en, part of the insulating layer 70 provided on the semiconductor substrate 60, and the gate 28e on the insulating layer 70. In this example, the seizure prevention transistor 28 is connected to the reset transistor 26 by sharing the n-type impurity region 67n with the reset transistor 26. The n-type impurity region 67n functions as the drain of the seizure prevention transistor 28. The n-type impurity region 68en functions as the source of the seizure prevention transistor 28. The part of the insulating layer 70 functions as a gate-insulating film 28ox of the seizure prevention transistor 28.

The amplification transistor 22 includes the n-type impurity regions 68bn and 68cn, part of the insulating layer 70, and the gate 22e on the insulating layer 70. The n-type impurity region 68bn functions as the drain of the amplification transistor 22. The n-type impurity region 68cn functions as the source of the amplification transistor 22. The part of the insulating layer 70 functions as a gate-insulating film 22ox of the amplification transistor 22.

The address transistor 24 includes the n-type impurity regions 68cn and 68dn, part of the insulating layer 70, and a gate 24e on the insulating layer 70. In this example, the address transistor 24 is connected to the amplification transistor 22 by sharing the n-type impurity region 68cn with the amplification transistor 22. The n-type impurity region 68cn functions as the drain of the address transistor 24. The n-type impurity region 68dn functions as the source of the address transistor 24. The part of the insulating layer 70 functions as a gate-insulating film 24ox of the address transistor 24.

The element separation region 69 is located between the n-type impurity regions 68bn and 68en. The element separation region 69 is, for example, an injection separation region. The injection separation region is, for example, a p-type impurity diffusion region. The element separation region 69 electrically separates the amplification transistor 22 and the seizure prevention transistor 28 from each other. The element separation region 69 may be a shallow trench isolation (STI) region.

The element separation region 69 is also located between pixels 10A adjacent to each other and electrically separates their signal detection circuits 14 from each other. The element separation region 69 is provided around the pair of the amplification transistor 22 and the address transistor 24 and around the pair of the reset transistor 26 and the seizure prevention transistor 28.

In this example, an insulating layer 72 is provided over the gates 28e, 26e, 22e, and 24e. The insulating layer 72 is, for example, a silicon oxide film. In this example, in addition, an insulating layer 71 is interposed between the insulating layer 72 and each of the gates 28e, 26e, 22e, and 24e. The insulating layer 71 is, for example, a silicon oxide film. The insulating layer 71 may have a stacking structure including a plurality of insulating layers. The insulating layer 72 may have a stacking structure including a plurality of insulating layers.

The stacking structures of the insulating layer 72 and the insulating layer 71 have a plurality of contact holes. Contact holes h1, h2, h3, h4, h5, h6, h7, h8, and h9 are provided through the insulating layer 72 and the insulating layer 71. The contact holes h1, h2, h3, h4, and h8 are provided at positions overlapping the n-type impurity regions 67n, 68an, 68bn, 68dn, and 68en, respectively. The contact plugs cp1, cp2, cp3, cp4, and cp8 are located at the positions of the contact holes h1, h2, h3, h4, and h8, respectively. The contact holes h5, h6, h7, and h9 are provided at positions overlapping the gates 26e, 22e, 24e, and 28e, respectively. The contact plugs cp5, cp6, and cp7 are located at the positions of the contact holes h5, h6, and h7, respectively. The plug pa3 is located at the position of the contact hole h9.

In the configuration exemplarily illustrated in FIG. 4, the wiring layer 80a is a layer including the contact plugs cp1 to cp8. The wiring layer 80a is typically a polysilicon layer doped with n-type impurities. The wiring layer 80a is located closest to the semiconductor substrate 60 among the wiring layers included in the wiring structure 80. The wiring layer 80b and the plugs pa1, pa2, and pa3 are located in the insulating layer 90a. The plug pa1 electrically connects the contact plug cp1 and the wiring layer 80b. The plug pa2 electrically connects the contact plug cp6 and the wiring layer 80b. The plug pa3 electrically connects the gate 28e of the seizure prevention transistor 28 and the wiring layer 80b. The n-type impurity region 67n, the gate 22e of the amplification transistor 22, and the gate 28e of the seizure prevention transistor 28 are electrically connected to one another through the contact plugs cp1 and cp6, the plugs pa1, pa2, and pa3, and the wiring layer 80b.

The wiring layer 80b is located in the insulating layer 90a. Part of the wiring layer 80b may include the vertical signal line 35, the address signal line 34, the power source wire 32, the reset signal line 36, the feedback line 53, and the like described above. The vertical signal line 35, the address signal line 34, the power source wire 32, the reset signal line 36, and the feedback line 53 are electrically connected to the n-type impurity region 68dn, the gate 24e, the n-type impurity region 68bn, the gate 26e, and the n-type impurity region 68an, respectively, through the contact plugs cp4, cp7, cp3, cp5, and cp2.

The plug pb located in the insulating layer 90b electrically connects the wiring layers 80b and 80c. The plug pc located in the insulating layer 90c electrically connects the wiring layers 80c and 80d. The plug pd located in the insulating layer 90d electrically connects the wiring layer 80d and the pixel electrode 12a of the photoelectric converter 12. The wiring layers 80b to 80d and the plugs pa1 to pa3 and pb to pd are typically made of metal or a metallic compound such as metallic nitride or metallic oxide. The metal is, for example, copper or tungsten. The metallic compound is, for example, metallic nitride or metallic oxide.

The plugs pa1 to pa3 and pb to pd, the wiring layers 80b to 80d, and the contact plugs cp1 and cp6 electrically connect the photoelectric converter 12 and the signal detection circuit 14 provided on the semiconductor substrate 60. The plugs pa1 to pa3 and pb to pd, the wiring layers 80b to 80d, the contact plugs cp1 and cp6, the pixel electrode 12a of the photoelectric converter 12, the gate 22e of the amplification transistor 22, the gate 28e of the seizure prevention transistor 28, and the n-type impurity region 67n are included in the charge storage capacitance that accumulates signal electric charge generated by the photoelectric converter 12. In this example, the signal electric charge is holes.

The n-type impurity regions provided in the semiconductor substrate 60 will be described below. Among the n-type impurity regions provided in the semiconductor substrate 60, the n-type impurity region 67n is located in the p-type impurity region 66p provided in the p-type semiconductor layer 65p as a p well. The n-type impurity region 67n is provided near the front surface of the semiconductor substrate 60, and at least part thereof is located at the front surface of the semiconductor substrate 60. A junction capacitance formed by the pn junction between the p-type impurity region 66p and the n-type impurity region 67n functions as capacitance that accumulates at least part of signal electric charge, and serves as part of the charge storage capacitance.

In the configuration exemplarily illustrated in FIG. 4, the n-type impurity region 67n includes a first region 67a and a second region 67b. The impurity concentration of the first region 67a of the n-type impurity region 67n is lower than those of the n-type impurity regions 68an and 68en. The second region 67b in the n-type impurity region 67n is provided in the first region 67a and has an impurity concentration higher than that of the first region 67a. The contact hole h1 is located on the second region 67b, and the contact plug cp1 is electrically connected to the second region 67b through the contact hole h1.

As described above, since the p-type semiconductor layer 65p is located adjacent to the p-type semiconductor layer 63p, the potential of the p-type semiconductor layer 65p can be controlled through the p-type semiconductor layer 63p when the imaging device 100A is in operation. With such a structure, it is possible to dispose regions having a relatively low impurity concentration around a part where the contact plug cp1 electrically connected to the photoelectric converter 12 contacts the semiconductor substrate 60. In this example, the part where the contact plug cp1 contacts the semiconductor substrate 60 is the second region 67b of the n-type impurity region 67n. The regions having a relatively low impurity concentration around the part are the first region 67a of the n-type impurity region 67n and the p-type impurity region 66p.

It is not essential to provide the second region 67b in the n-type impurity region 67n. However, when the impurity concentration of the second region 67b as a connection part between the contact plug cp1 and the semiconductor substrate 60 is set to a relatively high concentration, an effect of preventing the spread of a depleted layer around the connection part between the contact plug cp1 and the semiconductor substrate 60 is obtained. In other words, an effect of reducing depletion is obtained. When depletion around the part where the contact plug cp1 contacts the semiconductor substrate 60 is reduced in this manner, it is possible to reduce leakage current attributable to crystal defect of the semiconductor substrate 60 at the interface between the contact plug cp1 and the semiconductor substrate 60. The leakage current can be described as leakage current through interface levels. Furthermore, an effect of reducing contact resistance is obtained since the contact plug cp1 is connected to the second region 67b having a relatively high impurity concentration.

Moreover, in this example, the first region 67a having an impurity concentration lower than that of the second region 67b is interposed between the second region 67b of the n-type impurity region 67n and the p-type impurity region 66p, and the first region 67a is interposed between the second region 67b of the n-type impurity region 67n and the p-type semiconductor layer 65p. Since the first region 67a having a relatively low impurity concentration is located around the second region 67b, it is possible to reduce the intensity of an electric field generated due to the pn junction between the n-type impurity region 67n and the p-type semiconductor layer 65p or the p-type impurity region 66p. When the electric field intensity is reduced, leakage current attributable to the electric field generated due to the pn junction is reduced.

As schematically illustrated in FIG. 3A, in pixel 10A, the n-type impurity regions in the reset transistor 26 and the seizure prevention transistor 28 are separated from the n-type impurity regions in the amplification transistor 22 and the address transistor 24 by the element separation region 69 containing p-type impurities. Specifically, the n-type impurity regions 67n, 68an, and 68en are separated from the n-type impurity regions 67bn, 68cn, and 68dn by the element separation region 69. The n-type impurity region 67n and the element separation region 69 provided around the n-type impurity region 67n are located at the front surface of the semiconductor substrate 60 without contact with each other.

Specifically, the n-type impurity region 67n is provided in the p-type impurity region 66p having an impurity concentration lower than that of the p-type semiconductor layer 65p. A depleted layer region is generated between the n-type impurity region 67n and the p-type impurity region 66p. Typically, the crystal defect density near the front surface of the semiconductor substrate 60 is higher than the crystal defect density inside the semiconductor substrate 60. Thus, in a depleted layer region generated at a pn junction part at which the n-type impurity region 67n and the p-type impurity region 66p join each other, leakage current is greater in a depleted layer region formed at a junction part near the front surface of the semiconductor substrate 60 than in a depleted layer region generated at a pn junction part inside the semiconductor substrate 60.

Hereinafter, the depleted layer region generated at the junction part near the front surface of the semiconductor substrate 60 is referred to as an interface-depleted layer. Leakage current is likely to increase as the area of the interface-depleted layer increases. Thus, it is desirable to minimize the area of the interface-depleted layer exposed at the front surface of the semiconductor substrate 60. The area of the n-type impurity region 67n in a plan view may be less than that of the n-type impurity region 68an to reduce the area of the interface-depleted layer. For example, the area of the n-type impurity region 67n in a plan view may be equal to or less than ½ of the area of the n-type impurity region 68an. In this case, the width of the n-type impurity region 67n in a channel width direction may be equal to or less than ½ of the width of the n-type impurity region 68an in the channel width direction. The n-type impurity region 67n and the n-type impurity region 68an may be equal to each other in one of the widths in the channel width direction and the length in the channel length direction. Moreover, the area of the n-type impurity region 67n in a plan view may be less than the area of the n-type impurity regions 68bn to 68en.

The n-type impurity region 67n and the gate 26e may have an overlapping part in a plan view. The area of the n-type impurity region 67n in a plan view may be area obtained by subtracting the area of the overlapping part from the area of the n-type impurity region 67n.

The n-type impurity region 68an and the gate 26e may have an overlapping part in a plan view. The area of the n-type impurity region 68an in a plan view may be area obtained by subtracting the area of the overlapping part from the area of the n-type impurity region 68an. This description holds also when “68an” and “26e” are replaced with “68bn” and “22e”, respectively. The description holds also when “68an” and “26e” are replaced with “68cn” and “at least one of 22e and 24e”, respectively. The description holds also when “68an” and “26e” are replaced with “68en” and “28e”, respectively.

The meaning of employing area obtained through subtraction as the area of an impurity region as described above will be described below. In an impurity region, a part overlapping a gate in a plan view is less likely to be damaged at manufacturing than a part overlapping no gate in a plan view. Examples of damage at manufacturing include damage due to plasma processing used in a dry etching process, and damage due to ashing processing for flaking resist. From this, it can be understood that leakage current is unlikely to occur at the overlapping part. Thus, in the impurity region, only the area of a part overlapping no gate in a plan view needs to be considered in terms of reduction of the area of the interface-depleted layer.

The distance between the contact hole h1 provided in the n-type impurity region 67n and the gate 26e is referred to as a first distance. The distance between the contact hole h2 provided in the n-type impurity region 68an and the gate 26e is referred to as a second distance. It is easier to set the first distance to be less than the second distance by reducing the area of the n-type impurity region 67n. In the present embodiment, the first distance is less than the second distance. As described above, the impurity concentration of the n-type impurity region 67n is lower than the impurity concentration of the n-type impurity region 68an. The resistance value is likely to be high when the impurity concentration is low. In this situation, shortness of the first distance and shortness of a current path in the n-type impurity region 67n easily contributes to decrease of the resistance value in the n-type impurity region 67n.

The distance between the contact hole h3 provided in the n-type impurity region 68bn and the gate 22e is referred to as a third distance. The distance between the contact hole h4 provided in the n-type impurity region 68dn and the gate 24e is referred to as a fourth distance. The distance between the contact hole h8 provided in the n-type impurity region 68en and the gate 28e is referred to as a fifth distance. The first distance may be less than the third distance. The first distance may be less than the fourth distance. The first distance may be less than the fifth distance.

The present embodiment will be further described below by using terms such as a first transistor, a second transistor, a third transistor, a first gate, a first source, a first drain, a first gate-insulating film, a second gate, a second source, a second drain, a second gate-insulating film, a third gate, a third source, a third drain, and a third gate-insulating film.

The first transistor corresponds to the seizure prevention transistor 28. The second transistor corresponds to the amplification transistor 22. The third transistor corresponds to the reset transistor 26. The first gate, the first source, and the first drain correspond to the gate 28e, source, and drain of the seizure prevention transistor 28. The second gate, the second source, and the second drain correspond to the gate 22e, source, and drain of the amplification transistor 22. The third gate, the third source, and the third drain correspond to the gate 26e, source, and drain of the reset transistor 26. The first gate-insulating film corresponds to the gate-insulating film 28ox of the seizure prevention transistor 28, which is part of the insulating layer 70. The second gate-insulating film corresponds to the gate-insulating film 22ox of the amplification transistor 22, which is part of the insulating layer 70. The third gate-insulating film corresponds to the gate-insulating film 26ox of the reset transistor 26, which is part of the insulating layer 70. The use of any common reference sign is not intended for limited interpretation of the present disclosure.

The above-described characteristics related to the seizure prevention transistor 28 are applicable to the first transistor. The above-described characteristics related to the amplification transistor 22 are applicable to the second transistor. The above-described characteristics related to the reset transistor 26 are applicable to the third transistor. The above-described characteristics related to the gate 28e, source, and drain of the seizure prevention transistor 28 are applicable to the first gate, the first source, and the first drain. The above-described characteristics related to the gate 22e, source, and drain of the amplification transistor 22 are applicable to the second gate, the second source, and the second drain. The above-described characteristics related to the gate 26e, source, and drain of the reset transistor 26 are applicable to the third gate, the third source, and the third drain. The above-described characteristics related to the insulating layer 70 are applicable to the first gate-insulating film, the second gate-insulating film, and the third gate-insulating film.

In the present embodiment, the imaging device 100A includes the semiconductor substrate 60, the impurity region X, the first transistor, and the second transistor. The impurity region X is located in the semiconductor substrate 60. The impurity region X holds electric charge generated through photoelectric conversion. The first transistor includes the first source, the first drain, the first gate, and the first gate-insulating film. One of the first source and the first drain includes the impurity region X. The first gate is electrically connected to the impurity region X. The first gate-insulating film is located between the first gate and the semiconductor substrate 60. The second transistor includes the second gate and the second gate-insulating film. The second gate is electrically connected to the impurity region X. The second gate-insulating film is located between the second gate and the semiconductor substrate 60. Specifically, one of the first source and the first drain is the impurity region X.

In the present embodiment, the second transistor is the amplification transistor 22. The second transistor outputs signal voltage in accordance with the potential of the impurity region X. The first gate and the first source are not electrically connected to each other. The first gate and the first drain are not electrically connected to each other.

In the present embodiment, the imaging device 100A includes the third transistor. The third transistor includes the third source, the third drain, the third gate, and the third gate-insulating film. One of the third source and the third drain includes the impurity region X. The third gate-insulating film is located between the third gate and the semiconductor substrate 60. Specifically, one of the third source and the third drain is the impurity region X.

In the present embodiment, the imaging device 100A includes the element separation region 69. The element separation region 69 is located in the semiconductor substrate 60. In the present embodiment, the element separation region 69 is the injection separation region. Hereinafter, the element separation region 69 as the injection separation region is referred to as the injection separation region in some cases. However, the element separation region 69 may be an STI region.

In the present embodiment, the first gate includes a part overlapping the injection separation region in a plan view. The second gate includes a part overlapping the injection separation region in a plan view. The third gate includes a part overlapping the injection separation region in a plan view.

In the present embodiment, the first gate includes a part overlapping the first source and a part overlapping the first drain in a plan view. The second gate includes a part overlapping the second source and a part overlapping the second drain in a plan view. The third gate includes a part overlapping the third source and a part overlapping the third drain in a plan view.

In the present embodiment, the charge storage capacitance includes a plurality of kinds of components attributable to the first gate. The capacitance of the first kind is the gate capacitance of the first gate. The capacitance of the second kind is overlap capacitance between the first gate and the injection separation region since the first gate includes a part overlapping the injection separation region in a plan view. The capacitance of the third kind is overlap capacitance between the first gate and the first source and between the first gate 28e and the first drain since the first gate includes a part overlapping the first source and a part overlapping the first drain in a plan view.

In the present embodiment, the charge storage capacitance includes a plurality of kinds of components attributable to the second gate. The capacitance of the first kind is the gate capacitance of the second gate. The capacitance of the second kind is overlap capacitance between the second gate and the injection separation region since the second gate includes a part overlapping the injection separation region in a plan view. The capacitance of the third kind is overlap capacitance between the second gate and the second source and between the second gate 22e and the second drain since the second gate includes a part overlapping the second source and a part overlapping the second drain in a plan view.

In a transistor, gate capacitance Cg as the capacitance of the first kind is calculated by dividing the product of the dielectric constant 60 of vacuum, the specific dielectric constant EX of a gate-insulating film, and the area Sg of the gate in a plan view by the thickness Tx of the gate-insulating film. Specifically, the gate capacitance Cg is given by Expression 1 below.

Cg=ε0×εx×Sg/Tx (1)

Overlap capacitances of the second and third kinds are greater as the thickness Tx of the gate-insulating film is smaller. The overlap capacitance of the second kind is greater as the overlapping area of a gate and the injection separation region in a plan view is greater. The overlap capacitance of the third kind is greater as the overlapping area of the gate and the source and the overlapping area of the gate and the drain in a plan view are greater.

At least one kind of capacitance selected from a group consisting of the first, second, and third kinds related to the gate of a transistor other than the first transistor and the second transistor can be reflected on the charge storage capacitance. Generally, as for the first transistor, the second transistor, and the other transistor, the gate attributable components of the charge storage capacitance tend to be small in the following cases.
The gate-insulating film is thick.
The area of a gate in a plan view is small.

A gate having a small area in a plan view is easily achieved when the gate width is small and/or the gate length is short.

In the present embodiment, a thickness T1 of the first gate-insulating film is greater than a thickness T2 of the second gate-insulating film. This configuration is suitable for achieving the imaging device 100A having high image quality. The reason why the configuration is suitable for achieving the imaging device 100A having high image quality will be described below.

In the present embodiment, the second transistor is the amplification transistor 22. In this case, the condition of the thickness T1>the thickness T2 can be advantageous for achieving the imaging device 100A having high image quality. Specifically, when the charge storage capacitance is reduced, it is easier to ensure a charge-voltage conversion gain and sufficiently ensure the signal level relative to the noise level. Ensuring the signal level is advantageous in terms of achieving the imaging device 100A having high image quality. When only this advantage is considered, the first gate-insulating film and the second gate-insulating film are both preferably thick. However, as for the amplification transistor 22, in a case in which the gate-insulating film 22ox as the second gate-insulating film is thin, formation of trapping states due to impurities is reduced and random noise can be reduced. Reducing the random noise is advantageous in terms of achieving the imaging device 100A having high image quality. Moreover, drive performance of the amplification transistor 22 is easily obtained when the gate-insulating film 22ox as the second gate-insulating film is thin. As understood from the above description, the condition of the thickness T1>the thickness T2 can be advantageous in terms of achieving the imaging device 100A having high image quality. Output voltage of the second transistor has a value in accordance with the amount of electric charge accumulated in the charge storage capacitance. The above-described charge-voltage conversion gain means the output voltage of the second transistor relative to the amount of electric charge accumulated in the charge storage capacitance.

Consider a case in which the thickness T1 of the first gate-insulating film related to the first transistor is equal to the thickness T2 of the second gate-insulating film related to the second transistor. In this case, the first gate attributable component of the charge storage capacitance tends to be greater than the second gate attributable component of the charge storage capacitance. This is because, in the present embodiment, at least one relation selected from among the gate-source connection relation and the gate-drain connection relation is different between the first transistor and the second transistor. Thus, the amount of reduction of capacitance attributable to the first gate due to the increase of the thickness T1 is greater than the amount of reduction of capacitance attributable to the second gate due to the increase of the thickness T2. Accordingly, it is easier to reduce the charge storage capacitance when the thickness T1>the thickness T2 holds. This can be advantageous in terms of achieving the imaging device 100A having high image quality.

Etching such as dry etching is performed at manufacturing of the imaging device 100A in some cases. In the first transistor including the impurity region X in which electric charge is held, damage on the semiconductor substrate 60 due to etching can lead to an increase of leakage current. However, it is easy to achieve the thick first gate-insulating film when the thickness T1>the thickness T2 holds. This can reduce damage on the semiconductor substrate 60 due to etching and reduce noise in the first transistor. This is advantageous in terms of achieving the imaging device 100A having high image quality.

The three advantages of the condition of the thickness T1>the thickness T2 are described above. However, these are exemplary and may include any other advantage. For example, the thick first gate-insulating film has an advantage that gate leak in the first gate-insulating film is easily reduced. This can contribute to achieving the imaging device 100A having high image quality. Even when there is only one of the advantages, it can be thought that the advantage is effective in terms of achieving the imaging device 100A having high image quality.

An upper limit may be set to the thickness T1 of the first gate-insulating film. This also applies to the thicknesses of the other gate-insulating films. For example, controllability of the first transistor is easily ensured when the first gate-insulating film is thin.

In the present embodiment, the imaging device 100A includes the photoelectric converter 12 that generates electric charge through photoelectric conversion. Specifically, in the present embodiment, the photoelectric converter 12 is located above the semiconductor substrate 60.

In the present embodiment, the thickness T3 of the third gate-insulating film is greater than the thickness T2 of the second gate-insulating film. This configuration is suitable for achieving the imaging device 100A having high image quality. This is because, in the present embodiment, the third gate includes a part overlapping the impurity region X in a plan view, and thus the thick third gate-insulating film easily contributes to reduction of the charge storage capacitance, whereas the second gate includes no part overlapping the impurity region X.

With the above-described configuration, it is easy to achieve the thick third gate-insulating film. This can reduce damage on the semiconductor substrate 60 due to etching in the third transistor including the impurity region X in which electric charge is held, and can reduce noise. This is advantageous in terms of achieving the imaging device 100A having high image quality.

The thickness T3 may be equal to the thickness T2 or may be less than the thickness T2.

In the present embodiment, the thickness T1 of the first gate-insulating film is greater than the thickness T3 of the third gate-insulating film. However, the thickness T1 may be equal to the thickness T3 or may be less than the thickness T3.

The ratio T1/T2 of the thickness T1 of the first gate-insulating film relative to the thickness T2 of the second gate-insulating film is, for example, greater than or equal to 1.2 and less than or equal to 5. Specifically, the ratio T1/T2 may be greater than or equal to 1.3 and less than or equal to 3.5.

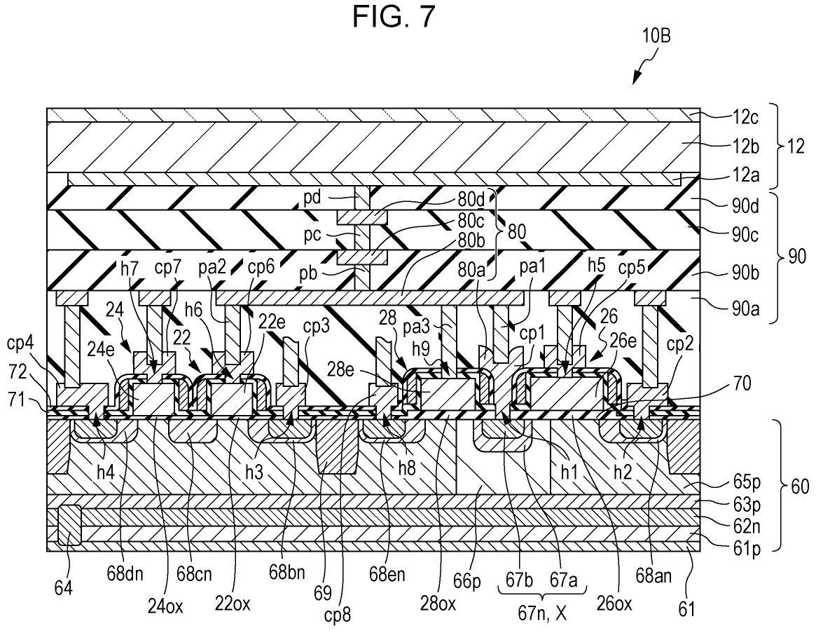

The ratio T1/T3 of the thickness T1 of the first gate-insulating film relative to the thickness T3 of the third gate-insulating film is, for example, greater than or equal to 0.5 and less than or equal to 5. Specifically, the ratio T1/T3 may be greater than or equal to 0.7 and less than or equal to 3.5. In the configuration example according to Embodiment 1 in FIG. 4, the ratio T1/T3 is greater than or equal to 1.2 and less than or equal to 5 as an example, and the ratio T1/T3 is greater than or equal to 1.3 and less than or equal to 3.5 as a specific example. In a configuration example according to Embodiment 2 in FIG. 7 to be described later, the ratio T1/T3 is greater than or equal to 0.5 and less than or equal to 2 as an example and greater than or equal to 0.7 and less than or equal to 1.5 as a specific example.

The thickness T1 is, for example, greater than or equal to 6.5 nm and less than or equal to 25 nm. The thickness T1 may be greater than or equal to 10 nm and less than or equal to 20 nm.

The thickness T2 is, for example, greater than or equal to 2.8 nm and less than or equal to 11 nm. The thickness T2 may be greater than or equal to 4.3 nm and less than or equal to 8.7 nm.

The thickness T3 is, for example, greater than or equal to 2.8 nm and less than or equal to 25 nm. The thickness T3 may be greater than or equal to 4.3 nm and less than or equal to 20 nm. In the configuration example according to Embodiment 1 in FIG. 4, the thickness T3 is greater than or equal to 2.8 nm and less than or equal to 11 nm as an example and greater than or equal to 4.3 nm and less than or equal to 8.7 nm as a specific example. In the configuration example according to Embodiment 2 in FIG. 7 to be described later, the thickness T3 is greater than or equal to 6.5 nm and less than or equal to 25 nm as an example and greater than or equal to 10 nm and less than or equal to 20 nm as a specific example.

The thickness of a gate-insulating film can be specified by a well-known method. The thickness of the gate-insulating film can be specified, for example, as described below. First, a transmissive electron microscope image of a section of the gate-insulating film is acquired. Subsequently, the thickness of the gate-insulating film is measured at a plurality of optional measurement points (for example, five points) by using the image. An average value of the thickness at the plurality of measurement points is employed as the thickness of the gate-insulating film. The average value is, for example, the arithmetic average value.

In the present embodiment, the width W1 of the first gate is less than the width W2 of the second gate. This configuration is suitable for achieving the imaging device 100A having high image quality. The reason why the configuration is suitable for achieving the imaging device 100A having high image quality will be described below.

Consider a case in which the mutual conductance gm of the second transistor needs to be increased, such as a case in which the second transistor is the amplification transistor 22. In this case, the condition of the width W1<the width W2 can be advantageous for achieving the imaging device 100A having high image quality. Specifically, when the charge storage capacitance is reduced, it is easier to ensure the charge-voltage conversion gain and sufficiently ensure the signal level relative to the noise level. Ensuring the signal level is advantageous in terms of achieving the imaging device 100A having high image quality. When only this advantage is considered, the widths of the first and second gates are both preferably small. However, as for the second transistor, when the width W2 of the second gate is large, the mutual conductance gm is ensured and drive power is easily obtained. Ensuring the drive power is advantageous in terms of achieving the imaging device 100A having high image quality. As understood from the above description, the condition of the width W1<the width W2 can be advantageous in terms of achieving the imaging device 100A having high image quality.

Consider another case in which the mutual conductance gm of the second transistor needs to be increased, such as a case in which the second transistor is the amplification transistor 22. In this case, it is advantageous to reduce the contact resistance of the source and/or drain of the second transistor, and thus it is advantageous to increase the number of contact plugs connected to the source and/or the drain. In this case, the width of the source and/or the drain is likely to be large, and thus the gate width is likely to be large. When this is considered together, it can be further understood that the condition of the width W1<the width W2 can be advantageous in terms of achieving the imaging device 100A having high image quality.

In the present embodiment, the width W3 of the third gate is less than the width W2 of the second gate. This configuration is suitable for achieving the imaging device 100A having high image quality. This is because, in the present embodiment, the third gate includes a part overlapping the impurity region X in a plan view, and thus the small width W3 easily contributes to the reduction of the charge storage capacitance, whereas the second gate includes no part overlapping the impurity region X.

The width W1 may be equal to the width W2 or may be greater than the width W2. The width W3 may be equal to the width W2 or may be greater than the width W2. The width W1 may be less than the width W3, may be equal to the width W3, or may be greater than the width W3.

The ratio W1/W2 of the width W1 of the first gate relative to the width W2 of the second gate is, for example, greater than or equal to 0.1 and less than or equal to 0.8. Specifically, the ratio W1/W2 may be greater than or equal to 0.12 and less than or equal to 0.7.

The length L1 of the first gate may be greater than the length L2 of the second gate. In this manner, the length L1 is easily ensured. Ensuring the length L1 is advantageous for preventing off-leak of the first transistor. However, it is not essential to employ a configuration with which the length L1 is easily ensured. For example, the length L1 may be less than the length L2.

In the present embodiment, the ratio L1/W1 of the length L1 of the first gate relative to the width W1 of the first gate is greater than the ratio L2/W2 of the length L2 of the second gate relative to the width W2 of the second gate. This configuration is suitable for achieving the imaging device 100A having high image quality. The reason why the configuration is suitable for achieving the imaging device 100A having high image quality will be described below.

When it is prioritized to ensure the gate length of a transistor than to ensure the gate width thereof, it is possible to prevent the occurrence of leakage current until the voltage between the gate and source of the transistor reaches its threshold voltage. With the configuration in which the ratio L1/W1 is greater than the ratio L2/W2, it is easy to increase the length L1. When the length L1 is long, it is possible to prevent the occurrence of leakage current until the voltage between the gate and source of the first transistor reaches its threshold voltage. Consider a case in which the mutual conductance gm of the second transistor needs to be increased to decrease resistance, such as a case in which the second transistor is the amplification transistor 22. In this case, as for the second transistor, when the width W2 of the second gate is large, the mutual conductance gm is ensured and drive power is easily obtained. With the configuration in which the ratio L1/W1 is greater than the ratio L2/W2, it is easy to increase the width W2. For the above-described reasons, the configuration in which the ratio L1/W1 is greater than the ratio L2/W2 is suitable for achieving the imaging device 100A having high image quality.

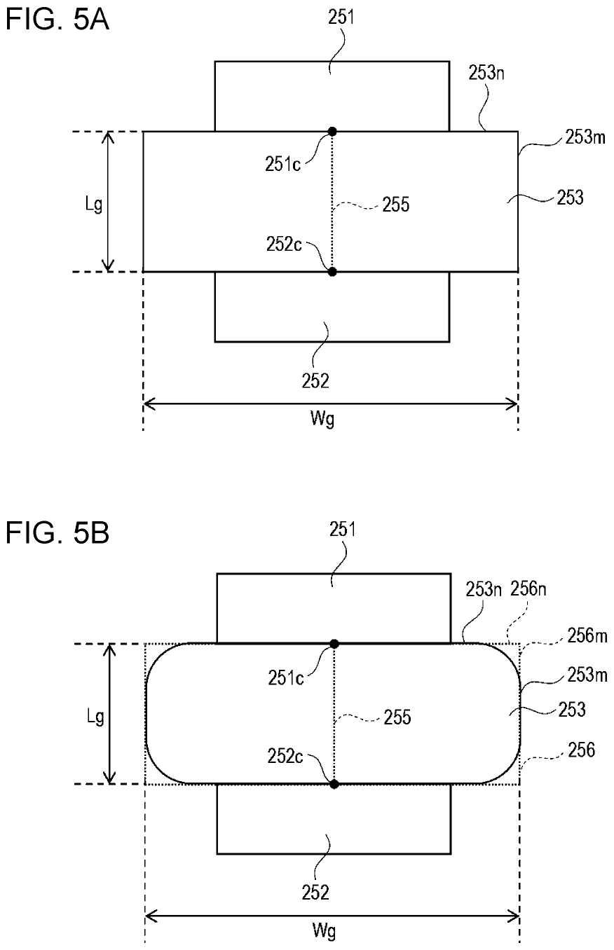

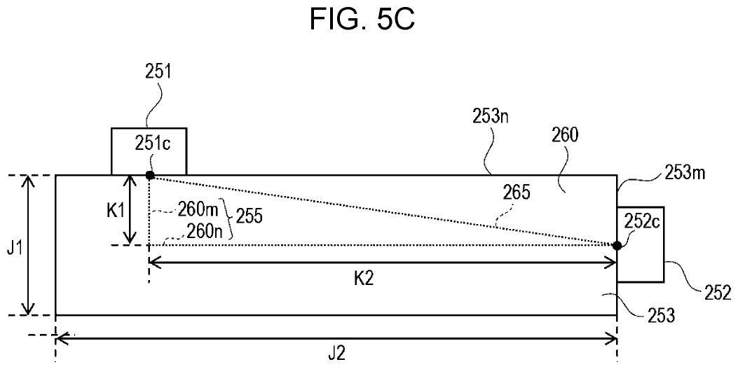

The following describes the length Lg and the width Wg of a gate. FIGS. 5A, 5B, and 5C are explanatory diagrams of the length Lg and the width Wg of the gate. A source 251 includes a part adjacent to the outline of a gate 253 in a plan view. The central point of this part is referred to as a source reference point 251c. A drain 252 includes a part adjacent to the outline of the gate 253 in a plan view. The central point of this part is referred to as a drain reference point 252c. A gate length direction is the direction from the source reference point 251c toward the drain reference point 252c or the direction from the drain reference point 252c toward the source reference point 251c. In FIGS. 5A to 5C, a line in this direction is schematically illustrated as a dotted line 255. The dotted line 255 may be a straight line or a bending line. The length Lg of the gate 253 is a dimension of the gate 253 in the gate length direction. The width Wg of the gate 253 is a dimension of the gate 253 in a gate width direction. The gate width direction is a direction orthogonal to the gate length direction in a plan view.

In the example illustrated in FIG. 5A, the gate 253 has a rectangular shape including a side 253m and a side 253n in a plan view. The direction in which the side 253m extends is parallel to the direction in which a straight line passing through the source reference point 251c and the drain reference point 252c extends. In this example, the length Lg is the length of the side 253m. The width Wg is the length of the side 253n.

In the example illustrated in FIG. 5B, the gate 253 has roundness in a plan view. FIG. 5B illustrates a minimum rectangle 256 that houses the gate 253 in a plan view. In the example illustrated in FIG. 5B, the length Lg and the width Wg can be defined based on the rectangle 256. Specifically, the rectangle 256 has a rectangular shape including a side 256m and a side 256n in a plan view. The direction in which the side 256m extends is parallel to the direction in which a straight line passing through the source reference point 251c and the drain reference point 252c extends. In this example, the length Lg is the length of the side 256m. The width Wg is the length of the side 256n.

In the example illustrated in FIG. 5C, the gate 253 has a rectangular shape including the side 253m and the side 253n in a plan view. The direction in which the side 253m extends and the direction in which the side 253n extends are deviated from the direction in which a straight line passing through the source reference point 251c and the drain reference point 252c extends. FIG. 5C illustrates a rectangle 260. The rectangle 260 is a rectangle having, as a diagonal line 265, a line segment connecting the source reference point 251c and the drain reference point 252c. The rectangle 260 includes a side 260m parallel to the side 253m, and a side 260n parallel to the side 253n. The side 260m and the side 260n each constitute part of the dotted line 255. In the example illustrated in FIG. 5C, the dotted line 255 has an L shape. The length of the side 253m is denoted by J1, the length of the side 253n is denoted by J2, the length of the side 260m is denoted by K1, and the length of the side 260n is denoted by K2.

In a modification of the example illustrated FIG. 5C, the gate 253 has roundness in a plan view. The idea in FIG. 5B is applicable to this modification. Specifically, description of the modification is obtained by replacing “the side 253m” and “the side 253n” in the description for FIG. 5C with “the side 256m” and “the side 256n”, for example.

In the present embodiment, area S1 of the first gate is less than area S2 of the second gate in a plan view. This configuration is suitable for achieving the imaging device 100A having high image quality. The reason why the configuration is suitable for achieving the imaging device 100A having high image quality will be described below.

When the area of a gate in a plan view is small, the gate attributable component of the charge storage capacitance is easily reduced. In the present embodiment, the second transistor is the amplification transistor 22. In this case, the second gate attributable component of the charge storage capacitance tends to be less than assumed from the size of the area S2 of the second gate in the second transistor because of the influence of the degree of modulation. Thus, the amount of reduction of the charge storage capacitance as a whole is easily ensured when the first gate attributable component of the charge storage capacitance is reduced by decreasing the area S1 of the first gate than when the second gate attributable component of the charge storage capacitance is reduced by decreasing the area S2 of the second gate. Accordingly, the charge storage capacitance is easily reduced with the configuration in which the area S1 of the first gate is less than the area S2 of the second gate. For the above-described reasons, the configuration in which the area S1 of the first gate is less than the area S2 of the second gate can be advantageous in terms of achieving the imaging device 100A having high image quality. A modulation degree He2 of a transistor is given by Expression 2 below. In Expression 2, Vs1 represents the potential of the source before change, Vs2 represents the potential of the source after change, Vg1 represents the potential of the gate before change, and Vg2 represents the potential of the gate after change. With the modulation degree He2 taken into consideration, contribution Cgs* of gate-source capacitance Cgs of the transistor in the charge storage capacitance is given by Expression 3 below. In Expression 3, (1−He2) is, for example, greater than or equal to 0.1 and less than or equal to 0.2.

He2=(Vs2−Vs1)/(Vg2−Vg1) (2)

Cgs*=(1−He2)Cgs (3)

As described above, in the present embodiment, the first gate-insulating film is relatively thick and the first gate has a relatively small area. This is advantageous for reducing the above-described capacitances of the first, second, and third kinds.

In the present embodiment, the photoelectric converter 12 is located above the semiconductor substrate 60. In this case, the configuration in which the first gate-insulating film is relatively thick and the first gate has a relatively small area easily contributes to reduction of the capacitances of the first, second, and third kinds. The reason for this is as follows. Specifically, in this case, no photodiode as a photoelectric converter needs to be provided on the semiconductor substrate 60. In the present embodiment, no photodiode is provided in the semiconductor substrate 60. Thus, the large first transistor can be employed. The capacitances of the first, second, and third kinds tend to be large when the first transistor is large. Thus, the configuration in which the first gate-insulating film is relatively thick and the first gate has a relatively small area easily contributes to reduction of the capacitances of the first, second, and third kinds.

However, the imaging device 100A may include, as a photoelectric converter, a photodiode provided in the semiconductor substrate 60. In this case as well, the configuration in which the first gate-insulating film is relatively thick and the first gate has a relatively small area can contribute to reduction of the capacitances of the first, second, and third kinds.

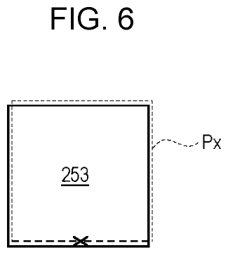

In a typical example, the above-described capacitances of the first, second, and third kinds are dominant as gate attributable components of the charge storage capacitance. However, capacitance of another kind exists as a gate attributable component of the charge storage capacitance. Such capacitance is, for example, fringe capacitance. The fringe capacitance depends on the perimeter length of a gate in a plan view. FIG. 6 is a diagram for description of a perimeter length Px of the gate 253. In FIG. 6, a dotted line indicating the perimeter length px is illustrated off the outline of the gate 253 for the sake of simplicity of illustration.

In the present embodiment, a perimeter length P1 of the first gate is less than a perimeter length P2 of the second gate in a plan view. This configuration is suitable for achieving the imaging device 100A having high image quality. The reason why the configuration is suitable for achieving the imaging device 100A having high image quality will be described below.

The fringe capacitance is easily reduced when the perimeter length of a gate in a plan view is short. In the present embodiment, the second transistor is the amplification transistor 22. In this case, the second gate attributable component of the charge storage capacitance tends to be less than assumed from the perimeter length P2 of the second gate in the second transistor because of the influence of the degree of modulation. Thus, the amount of reduction of the charge storage capacitance as a whole is easily ensured when the first gate attributable component of the charge storage capacitance is reduced by shortening the perimeter length P1 than when the second gate attributable component of the charge storage capacitance is reduced by shortening the perimeter length P2. Accordingly, the charge storage capacitance is easily reduced with the condition of the perimeter length P1<the perimeter length P2. Thus, this configuration can be advantageous in terms of achieving the imaging device 100A having high image quality.

In the present embodiment, the perimeter length P3 of the third gate is less than the perimeter length P2 of the second gate in a plan view.

As illustrated in FIG. 3B, in the present embodiment, the imaging device 100A includes the insulating layer 70. The insulating layer 70 includes a first part 70a and a second part 70b. The first part 70a includes the gate-insulating film 28ox as the first gate-insulating film. The second part 70b includes the gate-insulating film 22ox as the second gate-insulating film. The thickness of the first part 70a is greater than the thickness of the second part 70b.

In the example illustrated in FIG. 3B, the shortest line segment connecting the gate 28e as the first gate and the gate 22e as the second gate in a plan view is defined as a specific line segment 74. The middle point of the specific line segment 74 is defined as a specific point 75. In this case, the specific point 75 is located on the first part 70a in a plan view. With this configuration, the relatively thick first part 70a is easily expanded. In this manner, parasitic capacitance between the semiconductor substrate 60 below the first part 70a and an element such as a wire above the first part 70a can be reduced by contribution of the thick first part 70a. This can be advantageous in terms of achieving the imaging device 100A having high image quality.

In a specific example, the above-described element such as a wire and the semiconductor substrate 60 contain silicon. In this case, parasitic capacitance is likely to be generated between the element such as a wire and the semiconductor substrate 60. This means that the above-described effect of reducing parasitic capacitance is easily obtained. Silicon contained in the element such as a wire may be polysilicon. The element such as a wire may contain metal or metallic compound. The element such as a wire may be or may not be electrically connected to the first gate.

In a specific example, the above-described element such as a wire is located closer to the upper surface of the semiconductor substrate 60 than to the upper surface of the interlayer insulating layer 90. In this case, parasitic capacitance is likely to be generated between the element such as a wire and the semiconductor substrate 60. This means that the above-described effect of reducing parasitic capacitance is easily obtained. The above-described element such as a wire may be a wire 80x. The wire 80x may be included in the wiring layer located closest to the semiconductor substrate 60 among the wiring layers included in the wiring structure 80.

In the example illustrated in FIG. 3B, an imaging device 100A includes the wire 80x. The wire 80x is electrically connected to the gate 28e as the first gate. A region in which the semiconductor substrate 60, the first part 70a, and the wire 80x are arranged in the stated order in the thickness direction of the semiconductor substrate 60 is defined as a specific region 81. In this case, the specific region 81 extends from the inside of the gate 28e as the first gate to the outside thereof in a plan view. In other words, the specific region 81 extends across the outer edge of the gate 28e as the first gate in a plan view. With this configuration, parasitic capacitance between the semiconductor substrate 60 and the wire 80x provided outside can be reduced by contribution of the thick first part 70a even when the wire 80x extends from the inside of the gate 28e as the first gate to the outside thereof in a plan view. This is advantageous for reducing the charge storage capacitance, ensuring the charge-voltage conversion gain, and sufficiently ensuring the signal level relative to the noise level.

In a specific example, the wire 80x and the semiconductor substrate 60 contain silicon. In this case, parasitic capacitance is likely to be generated between the wire 80x and the semiconductor substrate 60. This means that the above-described effect of reducing parasitic capacitance is easily obtained. Silicon contained in the element may be polysilicon. The wire 80x may contain metal or metallic compound.

In a specific example, the wire 80x is located closer to the upper surface of the semiconductor substrate 60 than to the upper surface of the interlayer insulating layer 90. In this case, parasitic capacitance is likely to be generated between the wire 80x and the semiconductor substrate 60. This means that the above-described effect of reducing parasitic capacitance is easily obtained. The wire 80x may be included in the wiring layer located closest to the semiconductor substrate 60 among the wiring layers included in the wiring structure 80.

The first part 70a may overlap the entire impurity region X in a plan view. With this configuration, the impurity region X is easily protected from etching and the like.

In the present embodiment, the gate-insulating film 28ox as the first gate-insulating film is a gate oxide film. The gate-insulating film 22ox as the second gate-insulating film is a gate oxide film. The gate-insulating film 26ox as the third gate-insulating film is a gate oxide film. Specifically, the gate-insulating films 28ox, 22ox, and 26ox are made of silicon oxide. More specifically, the gate-insulating films 28ox, 22ox, and 26ox are made of silicon dioxide.

In the example illustrated in FIG. 4, the gate 28e as the first gate is a gate doped with n-type impurities. However, the gate 28e may be a gate doped with p-type impurities. With this configuration, the threshold voltage of the seizure prevention transistor 28 can be ensured by contribution of the work function of the gate 28e even when the channel dose of the seizure prevention transistor 28 as the first transistor is reduced. When the channel dose is reduced, it is possible to reduce PN junction electric field intensity around the n-type impurity region 67n provided in the p-type semiconductor layer 65p as a p well, thereby reducing leakage current.

Other embodiments will be described below. In the following description, any element common to an already described embodiment and an embodiment described thereafter is denoted by the same reference sign and description thereof is omitted in some cases. Descriptions related to the embodiments may be mutually applied without technological inconsistency. The embodiments may be mutually combined without technological inconsistency.

### Embodiment 2

FIG. 7 is a schematic sectional view of a device structure of a pixel according to Embodiment 2. The main difference between pixel 10B illustrated in FIG. 7 and pixel 10A illustrated in FIG. 4 is a gate-insulating film. Specifically, in the pixel 10B, the gate-insulating film 26ox below the gate 26e of the reset transistor 26 has the same film thickness as the gate-insulating film 28ox below the gate 28e of the seizure prevention transistor 28.

In Embodiment 1 described above, the gate-insulating film 26ox as the third gate-insulating film is thinner than the gate-insulating film 28ox as the first gate-insulating film. However, in Embodiment 2, the thickness T3 of the gate-insulating film 26ox as the third gate-insulating film is equal to the thickness T1 of the gate-insulating film 28ox as the first gate-insulating film. According to Embodiment 2, it is possible to increase the voltage resistance of the third gate-insulating film.

In a specific example of Embodiment 2, a negative voltage is applied to the third gate in a state in which the third transistor is turned off. The applied voltage is high to some extent and is, for example, higher than or equal to −2 V and lower than or equal to −1 V. Accordingly, an accumulated state can be achieved below the third gate instead of a depleted state, and dark current can be reduced. Moreover, the overlap capacitance of the third gate and the third source and the overlap capacitance of the third gate and the third drain can be reduced. This is advantageous in terms of ensuring the charge-voltage conversion gain, sufficiently ensuring the signal level relative to the noise level, and achieving the imaging device 100A having high image quality.

### Embodiment 3

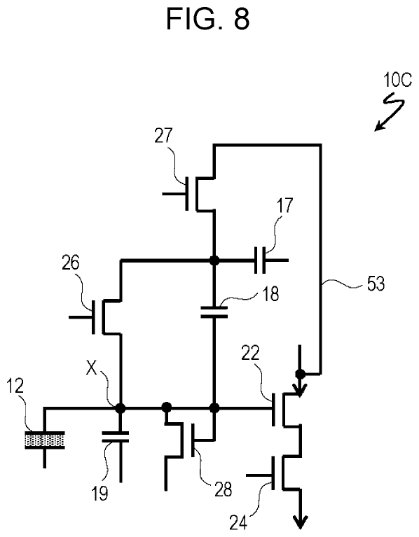

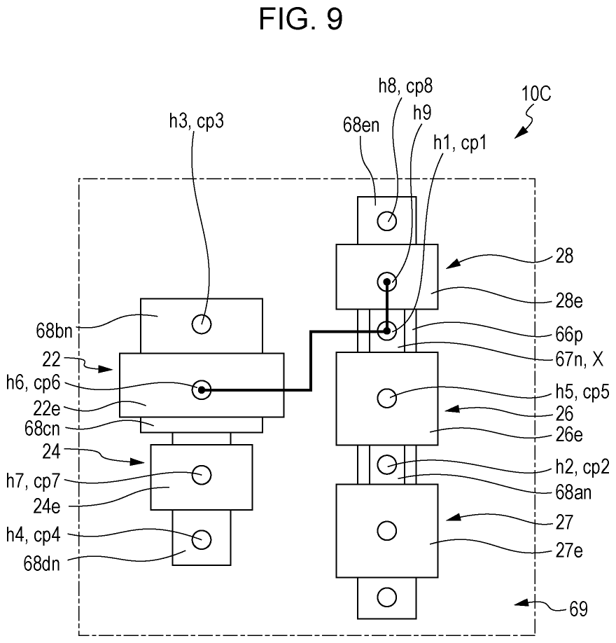

FIG. 8 is a diagram illustrating a circuit configuration in Embodiment 3. FIG. 9 is a plan view illustrating the arrangement in a pixel in Embodiment 3. In FIG. 9, an illustration of some elements such as wires is omitted. The main difference between pixel 10C illustrated in FIG. 8 and pixel 10A illustrated in FIG. 4 is feedback. Specifically, an in-pixel feedback circuit including a feedback transistor 27 is constituted in the pixel 10C. The pixel 10C also includes a capacitive element 17, a capacitive element 18, and a capacitive element 19.

In Embodiment 3, the feedback transistor 27 is a FET, and specifically, an N-channel MOSFET.

In Embodiment 3, the capacitive elements 17, 18, and 19 are MIM. In MIM, “M” stands for a conductor such as metal, metallic compound, or impurity-doped polysilicon. In MIM, “I” stands for an insulator such as oxide. Thus, MIM is a concept encompassing MOM. In MOM, “M” stands for a conductor such as metal, metallic compound, or impurity-doped polysilicon. In MOM, “O” stands for oxide.

One end of the capacitive element 18 is electrically connected to the impurity region X. The other end of the capacitive element 18 is electrically connected to one of the source and drain of the feedback transistor 27 and to one end of the capacitive element 17.

The gate 22e of the amplification transistor 22 is electrically connected to the impurity region X. One of the source and drain of the amplification transistor 22 is electrically connected to one of the source and drain of the address transistor 24. The other of the source and drain of the amplification transistor 22 is electrically connected to the other of the source and drain of the feedback transistor 27 through the feedback line 53.

The feedback transistor 27 includes a gate 27e. The gate 27e is electrically connected to a non-illustrated feedback control line. The feedback control line is electrically connected to, for example, the vertical scanning circuit 46. The voltage of the gate 27e is controlled by the vertical scanning circuit 46 when the imaging device is in operation.

The capacitive element 19 is electrically connected to the impurity region X. However, the capacitive element 19 may be omitted.

The impurity region X, the amplification transistor 22, the feedback transistor 27, the capacitive element 18, and the impurity region X are connected in the stated order. Through the connection, a signal attributable to the potential of the impurity region X can be negatively fed back to the impurity region X.

### Embodiment 4

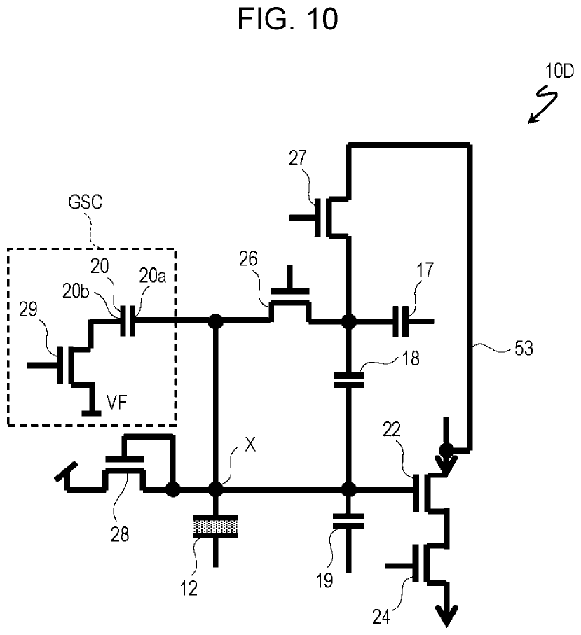

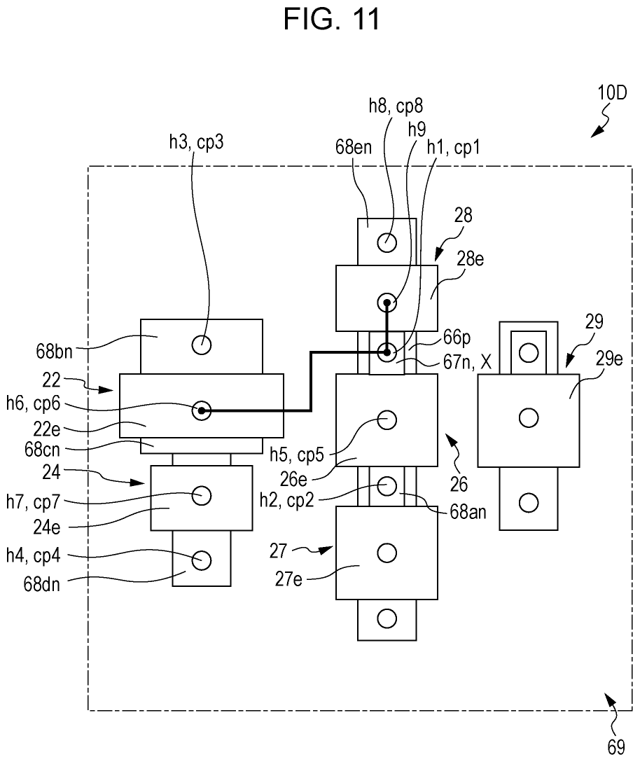

FIG. 10 is a diagram illustrating a circuit configuration in Embodiment 4. FIG. 11 is a plan view illustrating the arrangement in a pixel in Embodiment 4. In FIG. 11, an illustration of some elements such as wires is omitted. The main difference between pixel 10D illustrated in FIG. 10 and pixel 10C illustrated in FIG. 8 is a gain-switching circuit. Specifically, the pixel 10D includes a gain-switching circuit GSC. The gain-switching circuit GSC includes a gain-switching transistor 29 and a capacitive element 20.

In Embodiment 4, the gain-switching transistor 29 is a FET, and specifically, an N-channel MOSFET. The capacitive element 20 is MIM.

The impurity region X is electrically connected to a first terminal 20a of the capacitive element 20. One of the source and drain of the gain-switching transistor 29 is electrically connected to a second terminal 20b of the capacitive element 20. Control potential VF is applied from a control circuit to the other of the source and drain of the gain-switching transistor 29. The control potential VF is fixed potential. The level of the control potential VF that is direct-current potential may be different between durations. The control circuit can fix the potential of an application target through the application of the control potential VF.

The gain-switching transistor 29 includes a gate 29e. The gate 29e is electrically connected to a non-illustrated switching control line. The switching control line is electrically connected to, for example, the vertical scanning circuit 46. The voltage of the gate 29e is controlled by the vertical scanning circuit 46 when the imaging device is in operation.

In a duration in which the gain-switching transistor 29 is on, the control potential VF is supplied to the second terminal 20b through the gain-switching transistor 29. In this case, the potential of the second terminal 20b is fixed, and thus the capacitive element 20 behaves as capacitance and is included in the charge storage capacitance. However, in a duration in which the gain-switching transistor 29 is off, the control potential VF is not supplied to the second terminal 20b. In this case, the second terminal 20b is in a floating state, and thus the capacitive element 20 does not behave as capacitance and is not included in the charge storage capacitance. When the capacitive element 20 is set to behave as capacitance, the charge storage capacitance becomes relatively large and the charge-voltage conversion gain becomes relatively low. When the capacitive element 20 is set not to behave as capacitance, the charge storage capacitance becomes relatively small and the charge-voltage conversion gain becomes relatively high. Thus, it is possible to change the charge-voltage conversion gain by controlling whether the second terminal 20b is in the floating state.

### Embodiment 5

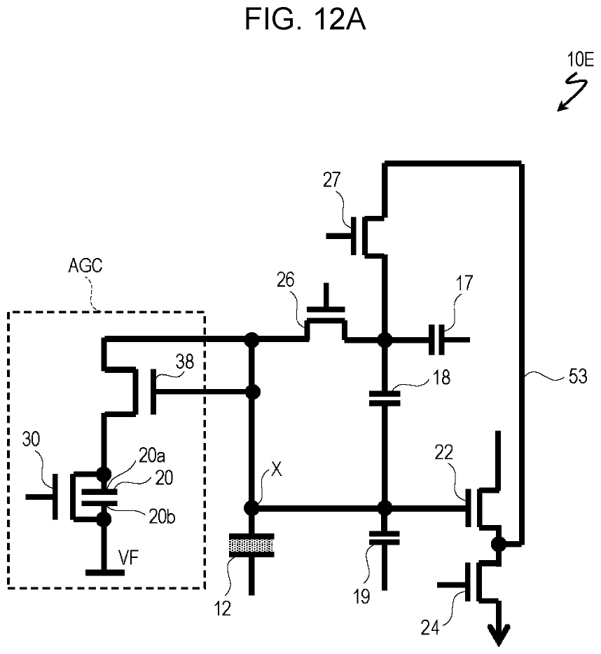

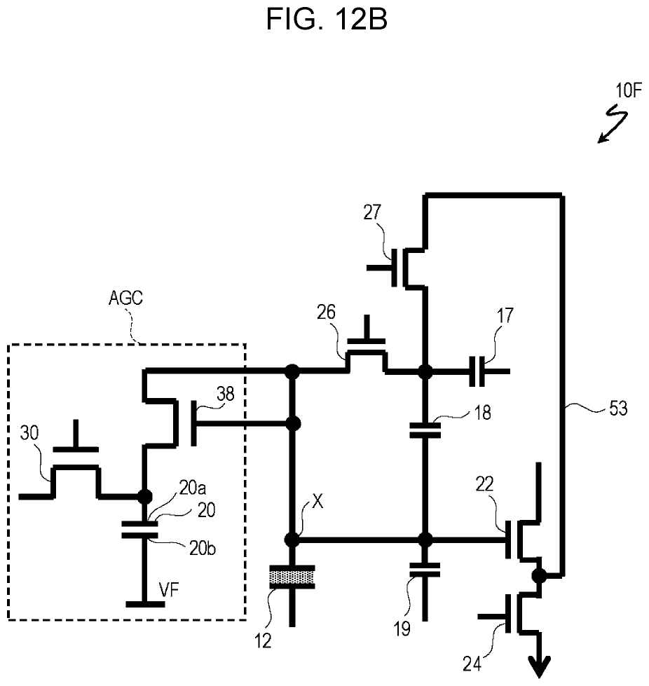

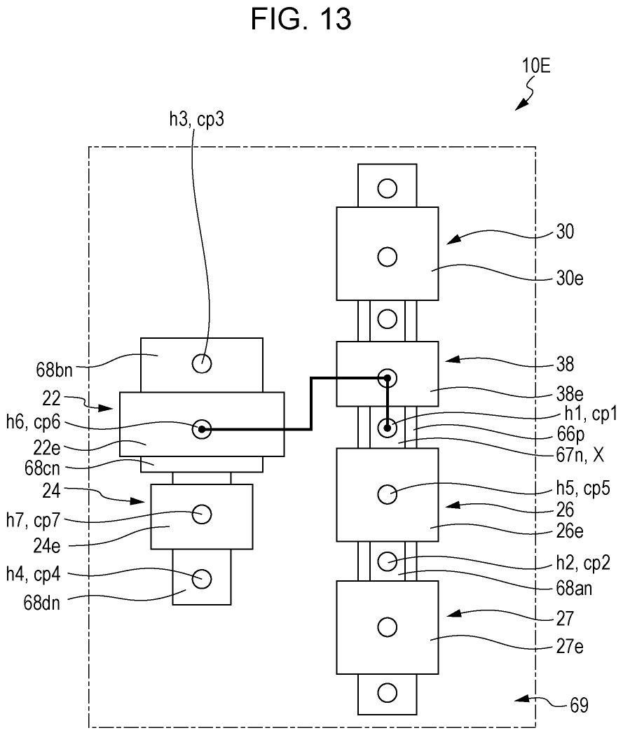

FIG. 12A is a diagram illustrating a circuit configuration in Embodiment 5. FIG. 13 is a plan view illustrating the arrangement in a pixel in Embodiment 5. In FIG. 13, an illustration of some elements such as wires is omitted. The main difference between pixel 10E illustrated in FIG. 12A and pixel 10D illustrated in FIG. 10 is an automatic gamma circuit. Specifically, the pixel 10E includes an automatic gamma circuit AGC. The automatic gamma circuit AGC includes an automatic gamma transistor 38, the capacitive element 20, and a specific reset transistor 30. FIG. 13 illustrates a gate 30e of the specific reset transistor 30.

One of the source and drain of the automatic gamma transistor 38 and a gate 38e of the automatic gamma transistor 38 are electrically connected to the impurity region X. The other of the source and drain of the automatic gamma transistor 38 is electrically connected to one of the source and drain of the specific reset transistor 30.

The capacitive element 20 is located between the source and drain of the specific reset transistor 30. Specifically, the first terminal 20a of the capacitive element 20 is electrically connected to the other of the source and drain of the automatic gamma transistor 38 and one of the source and drain of the specific reset transistor 30. The second terminal 20b of the capacitive element 20 is electrically connected to the other of the source and drain of the specific reset transistor 30. The control potential VF is applied from the control circuit to the second terminal 20b of the capacitive element 20.

Operation of the imaging device in Embodiment 5 will be described below.

At the start of exposure of the imaging device, the potential of the impurity region X is reset to reset potential by the reset transistor 26. The potential of the first terminal 20a of the capacitive element 20 is reset to the control potential VF by the specific reset transistor 30. The potential of the impurity region X is higher than the under-gate potential of the automatic gamma transistor 38. The potential of the first terminal 20a of the capacitive element 20 is higher than the potential of the impurity region X. The automatic gamma transistor 38 is off.

In Embodiment 5, signal electric charge is holes, and thus the potential of the impurity region X increases during the exposure. The impurity region X is electrically connected to the gate 38e of the automatic gamma transistor 38. Thus, the under-gate potential of the automatic gamma transistor 38 increases as the potential of the impurity region X increases.

As the under-gate potential of the automatic gamma transistor 38 increases along with the potential of the impurity region X, the under-gate potential of the automatic gamma transistor 38 eventually reaches the potential of the first terminal 20a.

When the potential of the gate 38e of the automatic gamma transistor 38 increases during the exposure, the voltage between the gate and source of the automatic gamma transistor 38 eventually exceeds its threshold voltage and the automatic gamma transistor 38 is turned on. Accordingly, the impurity region X and the first terminal 20a are electrically connected to each other through the automatic gamma transistor 38.

While the exposure is performed and the automatic gamma transistor 38 is on, a situation in which the under-gate potential of the automatic gamma transistor 38 is higher than the potential of the first terminal 20a and the potential of the impurity region X is higher than the under-gate potential of the automatic gamma transistor 38 can occur. In this situation, electrons are injected from the first terminal 20a to the impurity region X through the automatic gamma transistor 38. With the electron injection, the potential of the impurity region X decreases. Accordingly, the under-gate potential of the automatic gamma transistor 38 decreases as well. However, the potential of the first terminal 20a increases.

Through such electron injection, the potential of the impurity region X and the potential of the first terminal 20a are balanced. While being thus balanced, the potential of the impurity region X and the potential of the first terminal 20a can increase during the exposure. In this situation, the voltage between the first terminal 20a and the second terminal 20b changes along with generation of signal electric charge. Specifically, the charge storage capacitance is increased as the capacitive element 20 functions as part of the charge storage capacitance that accumulates electric charge. With the increase, the potential of the charge storage capacitance gradually changes. In this manner, automatic gamma that gamma correction is automatically performed is achieved.

In Embodiment 5, one of the source and drain of the amplification transistor 22 and one of the source and drain of the address transistor 24 are electrically connected to the feedback line 53. However, as in Embodiments 3 and 4, the other of the source and drain of the amplification transistor 22 may be electrically connected to the feedback line 53. Alternatively, the above-described connection in Embodiment 5 may be applied to Embodiments 3 and 4.

The automatic gamma transistor 38 may be referred to as the first transistor. The above description of “the seizure prevention transistor 28 as the first transistor” may be replaced with “the automatic gamma transistor 38 as the first transistor” without inconsistency. For example, the thickness of the first gate-insulating film of the automatic gamma transistor 38 as the first transistor is greater than the thickness of the second gate-insulating film of the second transistor.

FIG. 12B is a diagram illustrating a circuit configuration in a modification of Embodiment 5. In a pixel 10F illustrated in FIG. 12B, the other of the source and drain of the specific reset transistor 30 is not electrically connected to the second terminal 20b of the capacitive element 20. Specific reset potential is applied from the control circuit to the other of the source and drain of the specific reset transistor 30. The potential of the first terminal 20a of the capacitive element 20 can be reset to the specific reset potential by the specific reset transistor 30.

### Embodiment 6

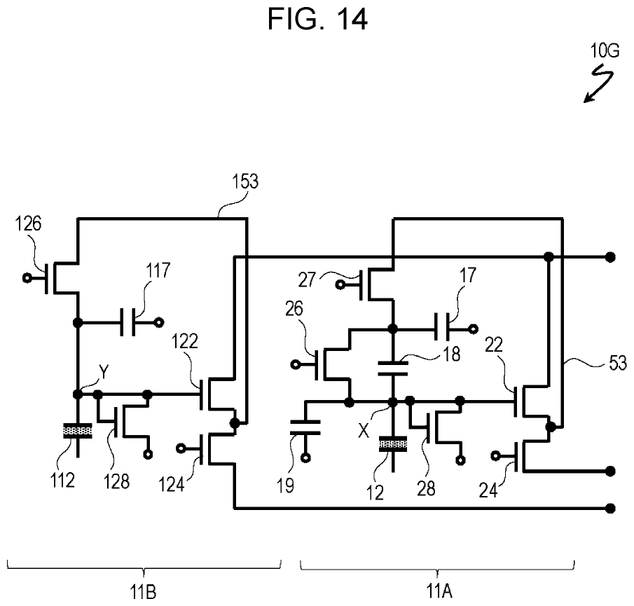

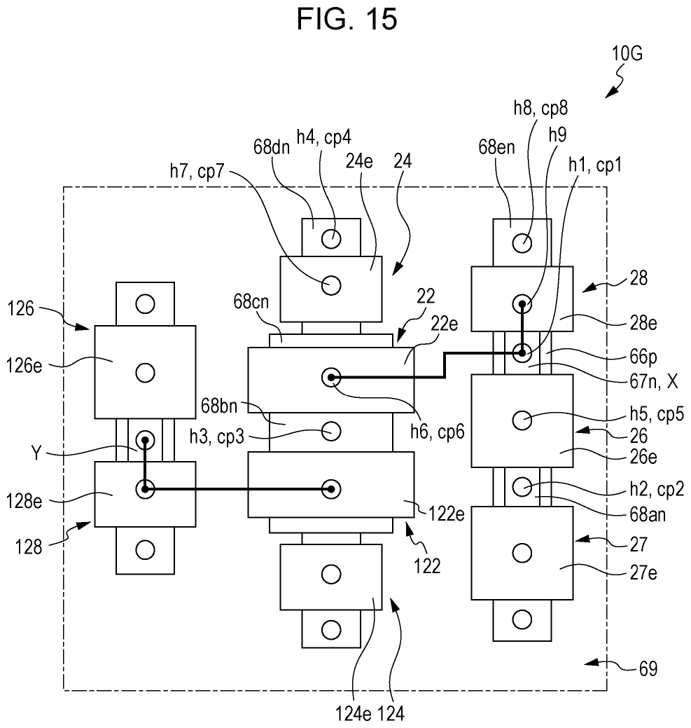

FIG. 14 is a diagram illustrating a circuit configuration in Embodiment 6. FIG. 15 is a plan view illustrating the arrangement in a pixel in Embodiment 6. In FIG. 15, an illustration of some elements such as wires is omitted. The main difference between pixel 10G illustrated in FIG. 14 and pixel 10C illustrated in FIG. 8 is the number of cells in one pixel. Specifically, in Embodiment 6, a high sensitivity cell 11A and a high saturation cell 11B are constituted in one pixel 10G.

The high-sensitivity cell 11A has the same configuration as the pixel 10C illustrated in FIG. 8.

The high saturation cell 11B includes a second amplification transistor 122, a second reset transistor 126, a second address transistor 124, a second seizure prevention transistor 128, a second photoelectric converter 112, and a capacitive element 117.

The high saturation cell 11B includes an impurity region Y. The impurity region Y serves as one of the source and drain of the second reset transistor 126 and one of the source and drain of the second seizure prevention transistor 128. The impurity region Y is electrically connected to a gate 122e of the second amplification transistor 122, a gate 128e of the second seizure prevention transistor 128, and the second photoelectric converter 112.

The second amplification transistor 122 outputs signal voltage in accordance with the amount of signal electric charge generated by the second photoelectric converter 112. One of the source and drain of the second amplification transistor 122 and one of the source and drain of the second address transistor 124 are electrically connected to the other of the source and drain of the second reset transistor 126 through a second feedback line 153.

FIG. 15 illustrates a gate 124e of the second address transistor 124, a gate 126e of the second reset transistor 126, and the gate 128e of the second seizure prevention transistor 128.

The second amplification transistor 122 may have the characteristics described above for the amplification transistor 22. The second reset transistor 126 may have the characteristics described above for the reset transistor 26. The second address transistor 124 may have the characteristics described above for the address transistor 24. The second seizure prevention transistor 128 may have the characteristics described above for the seizure prevention transistor 28. The second photoelectric converter 112 may have the characteristics described above for the photoelectric converter 12. The capacitive element 117 may have the characteristics described above for the capacitive element 17.

In Embodiment 6, the thickness of the gate-insulating film of the second seizure prevention transistor 128 is greater than the thickness of the gate-insulating film of the second amplification transistor 122. However, the thickness of the gate-insulating film of the second seizure prevention transistor 128 may be equal to the thickness of the gate-insulating film of the second amplification transistor 122. Alternatively, the gate-insulating film of the second seizure prevention transistor 128 may be thinner than the gate-insulating film of the second amplification transistor 122. Typically, the area of a photoelectric converter 112 in a plan view is less than the area of the photoelectric converter 12.

### Embodiment 7

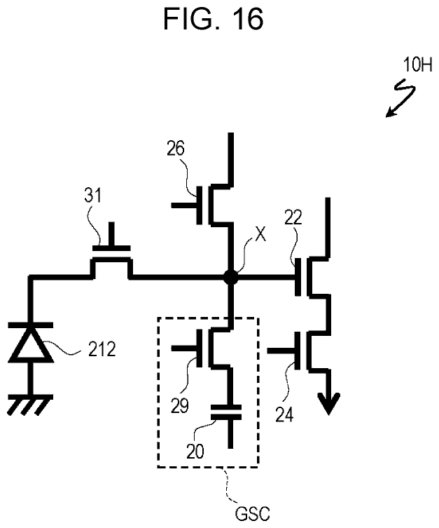

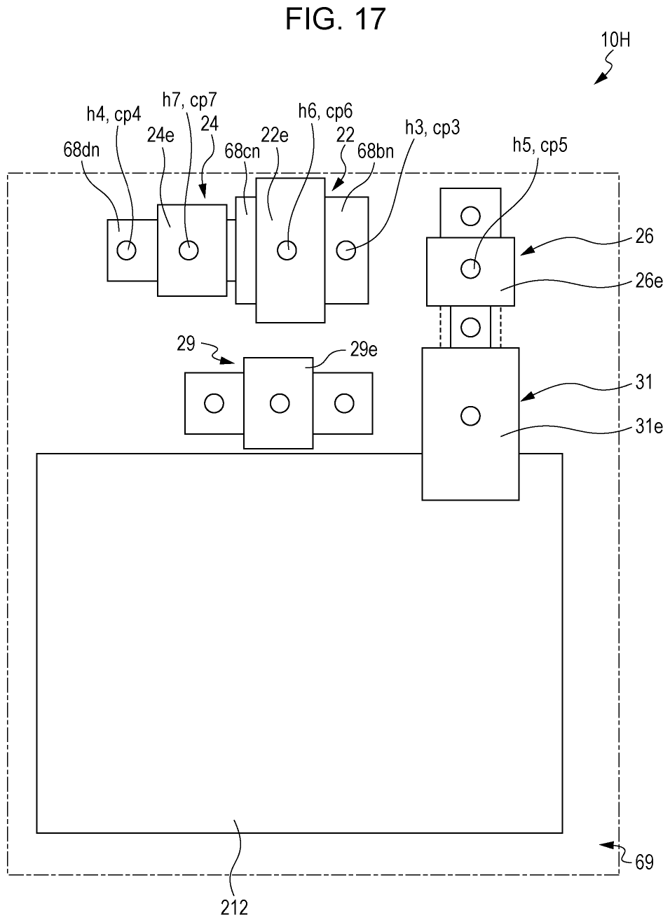

FIG. 16 is a diagram illustrating a circuit configuration in Embodiment 7. FIG. 17 is a plan view illustrating the arrangement in a pixel in Embodiment 7. In FIG. 17, an illustration of some elements such as wires is omitted.

In Embodiment 7, a pixel 10H includes the amplification transistor 22, the reset transistor 26, the address transistor 24, a forwarding transistor 31, a photoelectric converter 212, and the gain-switching circuit GSC. The gain-switching circuit GSC includes the gain-switching transistor 29 and the capacitive element 20.

The photoelectric converter 212 is a photodiode. Specifically, the photoelectric converter 212 is a silicon photodiode.

One of the source and drain of the forwarding transistor 31 is the impurity region X. The other of the source and drain of the forwarding transistor 31 is electrically connected to the photoelectric converter 212. Whether the impurity region X and the photoelectric converter 212 are electrically connected to each other is switched by turning on or off the forwarding transistor 31. The gate of the amplification transistor 22 is electrically connected to the impurity region X. The amplification transistor 22 outputs signal voltage in accordance with the potential of the impurity region X. One of the source and drain of the amplification transistor 22 is electrically connected to one of the source and drain of the address transistor 24.

The impurity region X is electrically connected to the capacitive element 20 through the gain-switching transistor 29. The impurity region X serves as one of the source and drain of the forwarding transistor 31, one of the source and drain of the gain-switching transistor 29, and one of the source and drain of the reset transistor 26.

The forwarding transistor 31 includes a gate 31e. The gate 31e is electrically connected to a non-illustrated forwarding control line. The forwarding control line is electrically connected to, for example, the vertical scanning circuit 46. The voltage of the gate 31e is controlled by the vertical scanning circuit 46 when the imaging device is in operation.

In a duration in which the gain-switching transistor 29 is on, the capacitive element 20 is electrically connected to the impurity region X through the gain-switching transistor 29. The capacitive element 20 is included in the charge storage capacitance. However, in a duration in which the gain-switching transistor 29 is off, the capacitive element 20 is not electrically connected to the impurity region X. The capacitive element 20 is not included in the charge storage capacitance. In this manner, whether the capacitive element 20 is included in the charge storage capacitance is switched as the gain-switching transistor 29 is turned on and off. Accordingly, the charge-voltage conversion gain can be changed.

Embodiment 7 will be further described below by using the term “first transistor”. The first transistor corresponds to the gain-switching transistor 29. The above-described characteristics related to the gain-switching transistor 29 are applicable to the first transistor.

In Embodiment 7, the imaging device includes the semiconductor substrate 60, the impurity region X, the first transistor, the capacitive element 20, and the amplification transistor 22 as the second transistor. The impurity region X is located in the semiconductor substrate 60. The impurity region X holds electric charge generated through photoelectric conversion. The first transistor includes the first source, the first drain, the first gate, and the first gate-insulating film. One of the first source and the first drain includes the impurity region X. The first gate-insulating film is located between the first gate and the semiconductor substrate 60. The capacitive element 20 is electrically connected to the other of the first source and the first drain. The second transistor includes the second gate and the second gate-insulating film. The second gate is electrically connected to the impurity region X, and the second gate-insulating film is located between the second gate and the semiconductor substrate 60. The thickness of the first gate-insulating film is greater than the thickness of the second gate-insulating film. This configuration is suitable for achieving the imaging device 100A having high image quality. Specifically, one of the first source and the first drain is the impurity region X.

In Embodiment 7, the second transistor is turned on in accordance with the potential of the impurity region X change.

In Embodiment 7, the imaging device includes the reset transistor 26 as the third transistor that resets the potential of the impurity region X.

The above-described characteristics related to “the seizure prevention transistor 28 as the first transistor” are applicable to “the gain-switching transistor 29 as the first transistor” without inconsistency. For example, in Embodiment 7, the width of the gate 29e of the gain-switching transistor 29 as the first transistor is less than the width of the gate 22e of the second transistor. The first gate-insulating film is a gate oxide film. Specifically, the first gate-insulating film is made of silicon oxide. More specifically, the first gate-insulating film is made of silicon dioxide.

Embodiment 7 will be further described below by using the term “fourth transistor”. The fourth transistor corresponds to the forwarding transistor 31. The above-described characteristics related to the forwarding transistor 31 are applicable to the fourth transistor.

In Embodiment 7, the imaging device includes the fourth transistor and the photoelectric converter 212. The fourth transistor includes a fourth source, a fourth drain, a fourth gate, and a fourth gate-insulating film. One of the fourth source and the fourth drain includes the impurity region X. The fourth gate-insulating film is located between the fourth gate and the semiconductor substrate 60. The photoelectric converter 212 generates electric charge through photoelectric conversion. Whether the impurity region X and the photoelectric converter 212 are electrically connected to each other is switched as the fourth transistor is turned on and off. Specifically, one of the fourth source and the fourth drain is the impurity region X.

In Embodiment 7, the fourth gate-insulating film is a gate oxide film. Specifically, the fourth gate-insulating film is made of silicon oxide. More specifically, the fourth gate-insulating film is made of silicon dioxide.

Other Circuit Examples Including Photodiode

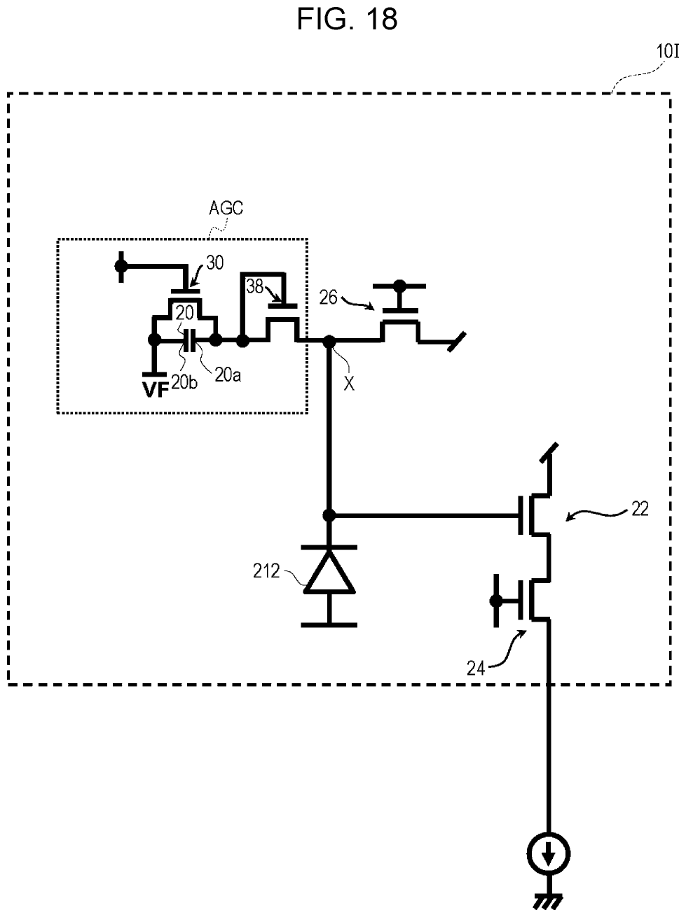

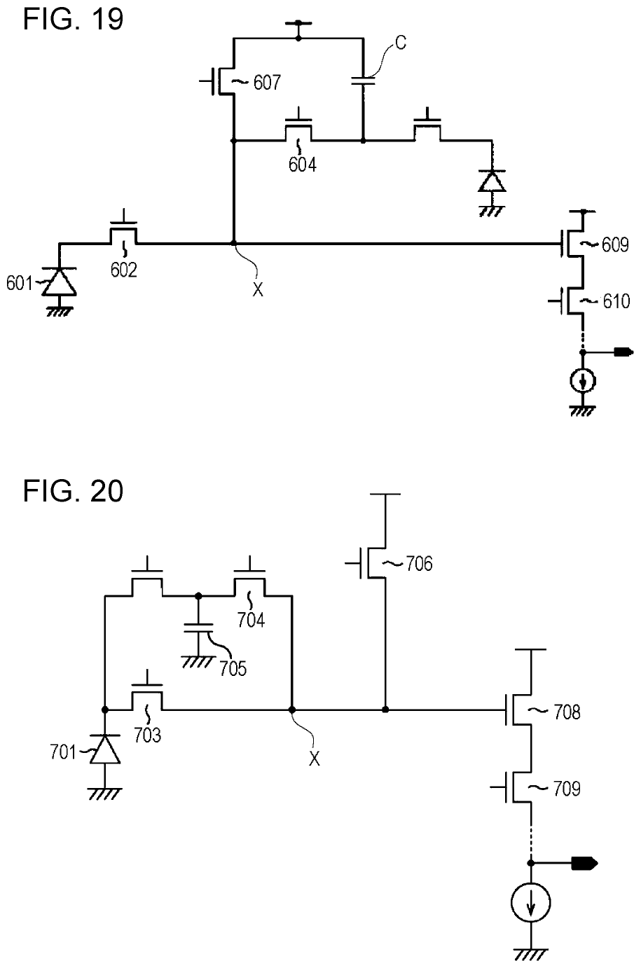

Circuit examples including a photodiode will be described below. FIGS. 18 to 22 are diagrams illustrating a circuit example including a photodiode. Specifically, a pixel illustrated in FIG. 18 is an automatic-gamma pixel including a photodiode. Pixels illustrated in FIGS. 19 to 22 are gain-switching pixels including a photodiode.

Circuit Example Illustrated in FIG. 18

A pixel 10I illustrated in FIG. 18 includes the amplification transistor 22, the reset transistor 26, the address transistor 24, the photoelectric converter 212, and the automatic gamma circuit AGC. The automatic gamma circuit AGC includes the automatic gamma transistor 38, the capacitive element 20, and the specific reset transistor 30.

Unlike the pixel 10E, the pixel 10I includes the photoelectric converter 212 as a photodiode. The photoelectric converter 212 generates electric charge through photoelectric conversion. The generated electric charge is accumulated in the impurity region X. The impurity region X serves as one of the source and drain of the reset transistor 26 and one of the source and drain of the automatic gamma transistor 38. Signal electric charge is electrons.

One of the source and drain of the automatic gamma transistor 38 is electrically connected to the photoelectric converter 212. The other of the source and drain of the automatic gamma transistor 38 and the gate 38e of the automatic gamma transistor 38 are electrically connected to one of the source and drain of the specific reset transistor 30.

The capacitive element 20 is located between the source and drain of the specific reset transistor 30. Specifically, the first terminal 20a of the capacitive element 20 is electrically connected to the other of the source and drain of the automatic gamma transistor 38, the gate 38e of the automatic gamma transistor 38, and one of the source and drain of the specific reset transistor 30. The second terminal 20b of the capacitive element 20 is electrically connected to the other of the source and drain of the specific reset transistor 30. The control potential VF is applied from the control circuit to the second terminal 20b of the capacitive element 20.

At the start of exposure of the imaging device, the potential of the impurity region X is reset to reset potential by the reset transistor 26. The potential of the first terminal 20a of the capacitive element 20 is reset to the control potential VF by the specific reset transistor 30. The potential of the first terminal 20a of the capacitive element 20 is higher than the under-gate potential of the automatic gamma transistor 38. The potential of the impurity region X is higher than the potential of the first terminal 20a of the capacitive element 20. The automatic gamma transistor 38 is off.

In the example illustrated in FIG. 18, the potential of the impurity region X decreases during the exposure since signal electric charge is electrons.

When the potential of the impurity region X decreases as the exposure proceeds, the voltage between the gate and source of the automatic gamma transistor 38 eventually exceeds its threshold voltage and the automatic gamma transistor 38 is turned on. Accordingly, the impurity region X and the first terminal 20a are electrically connected to each other through the automatic gamma transistor 38.

While the exposure is performed and the automatic gamma transistor 38 is on, a situation in which the under-gate potential of the automatic gamma transistor 38 is lower than the potential of the first terminal 20a and the potential of the impurity region X is lower than the under-gate potential of the automatic gamma transistor 38 can occur. In this situation, electrons flow from the impurity region X to the first terminal 20a through the automatic gamma transistor 38. With this electron movement, the potential of the impurity region X increases. Accordingly, the under-gate potential of the automatic gamma transistor 38 increases as well. However, the potential of the first terminal 20a decreases.

Through such electric charge movement, the potential of the impurity region X and the potential of the first terminal 20a are balanced. While being balanced, the potential of the impurity region X and the potential of the first terminal 20a can decrease during the exposure. In this situation, the voltage between the first terminal 20a and the second terminal 20b changes along with generation of signal electric charge. Specifically, the charge storage capacitance increases as the capacitive element 20 functions as part of the charge storage capacitance that accumulates electric charge. With the increase, the potential of the impurity region X gradually changes. In this manner, automatic gamma that gamma correction is automatically performed is achieved.

In the example illustrated in FIG. 18, the imaging device includes the semiconductor substrate 60, the impurity region X, the automatic gamma transistor 38 as the first transistor, and the amplification transistor 22 as the second transistor. The impurity region X is located in the semiconductor substrate 60. The impurity region X holds electric charge generated through photoelectric conversion. The first transistor includes the first source, the first drain, the first gate, and the first gate-insulating film. One of the first source and the first drain includes the impurity region X. The first gate is electrically connected to the other of the first source and the first drain. The first gate-insulating film is located between the first gate and the semiconductor substrate 60. The second transistor includes the second gate and second gate-insulating film 22ox. The second gate is electrically connected to the impurity region X. The second gate-insulating film is located between the second gate and the semiconductor substrate 60. The thickness of the first gate-insulating film is greater than the thickness of the second gate-insulating film. This configuration is suitable for achieving the imaging device 100A having high image quality. Specifically, one of the first source and the first drain is the impurity region X.

Circuit Example Illustrated in FIG. 19

FIG. 19 is FIG. 4 of WO 2016/147885 in which the numerical value of each reference sign is changed through addition of 500 and reference signs C and X are added. Specifically, FIG. 19 illustrates a photodiode 601 as a photoelectric converter that is a silicon photodiode, a forwarding transistor 602, a reset transistor 607, a gain-switching transistor 604, a capacitive element C, an amplification transistor 609, and an address transistor 610.

The impurity region X serves as one of the source and drain of the forwarding transistor 602, one of the source and drain of the reset transistor 607, and one of the source and drain of the gain-switching transistor 604. The other of the source and drain of the forwarding transistor 602 is electrically connected to the photodiode 601. The other of the source and drain of the gain-switching transistor 604 is electrically connected to the capacitive element C. The impurity region X is electrically connected to the gate of the amplification transistor 609. One of the source and drain of the amplification transistor 609 is electrically connected to one of the source and drain of the address transistor 610.

The gain-switching transistor 604 may be referred to as the first transistor. The amplification transistor 609 may be referred to as the second transistor. The reset transistor 607 may be referred to as the third transistor. The forwarding transistor 602 may be referred to as the fourth transistor. The technologies described above in the embodiments are applicable to the circuit example illustrated in FIG. 19 without inconsistency. In this case, the above description holds when “the gain-switching transistor 29 as the first transistor” is replaced with “the gain-switching transistor 604 as the first transistor”, “the amplification transistor 22 as the second transistor” is replaced with “the amplification transistor 609 as the second transistor”, “the reset transistor 26 as the third transistor” is replaced with “the reset transistor 607 as the third transistor”, and “the forwarding transistor 31 as the fourth transistor” is replaced with “the forwarding transistor 602 as the fourth transistor”. For example, the thickness of the first gate-insulating film of the first transistor is greater than the thickness of the second gate-insulating film of the second transistor.

Circuit Example Illustrated in FIG. 20

FIG. 20 is FIG. 4 of WO 2017/169885 in which the numerical value of each reference sign is changed through addition of 600 and a reference sign X is added. Specifically, FIG. 20 illustrates a photodiode 701 as a photoelectric converter that is a silicon photodiode, a forwarding transistor 703, a reset transistor 706, a gain-switching transistor 704, a capacitive element 705, an amplification transistor 708, and an address transistor 709.

The impurity region X serves as one of the source and drain of the forwarding transistor 703, one of the source and drain of the reset transistor 706, and one of the source and drain of the gain-switching transistor 704. The other of the source and drain of the forwarding transistor 703 is electrically connected to the photodiode 701. The other of the source and drain of the gain-switching transistor 704 is electrically connected to the capacitive element 705. The impurity region X is electrically connected to the gate of the amplification transistor 708. One of the source and drain of the amplification transistor 708 is electrically connected to one of the source and drain of the address transistor 709.

The gain-switching transistor 704 may be referred to as the first transistor. The amplification transistor 708 may be referred to as the second transistor. The reset transistor 706 may be referred to as the third transistor. The forwarding transistor 703 may be referred to as the fourth transistor. The technologies described above in the embodiments are applicable to the circuit example illustrated in FIG. 20 without inconsistency. In this case, the above description holds when “the gain-switching transistor 29 as the first transistor” is replaced with “the gain-switching transistor 704 as the first transistor”, “the amplification transistor 22 as the second transistor” is replaced with “the amplification transistor 708 as the second transistor”, “the reset transistor 26 as the third transistor” is replaced with “the reset transistor 706 as the third transistor”, and “the forwarding transistor 31 as the fourth transistor” is replaced with “the forwarding transistor 703 as the fourth transistor”. For example, the thickness of the first gate-insulating film of the first transistor is greater than the thickness of the second gate-insulating film of the second transistor.

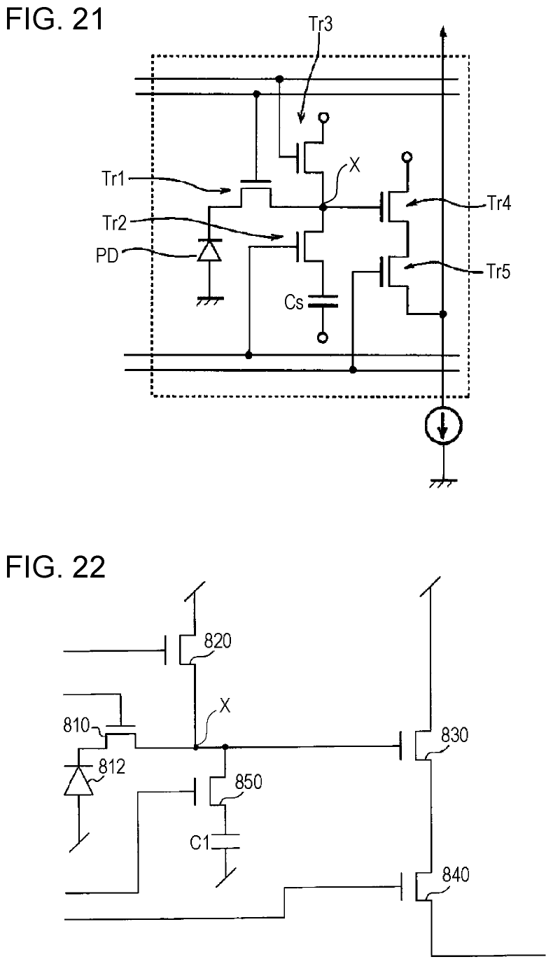

Circuit Example Illustrated in FIG. 21

FIG. 21 is FIG. 1 of Japanese Patent No. 4317115 in which a reference sign Xis added. Specifically, FIG. 21 illustrates a photodiode PD as a photoelectric converter that is a silicon photodiode, a forwarding transistor Tr1, a reset transistor Tr3, a gain-switching transistor Tr2, a capacitive element Cs, an amplification transistor Tr4, and an address transistor Tr5.

The impurity region X serves as one of the source and drain of the forwarding transistor Tr1, one of the source and drain of the reset transistor Tr3, and one of the source and drain of the gain-switching transistor Tr2. The other of the source and drain of the forwarding transistor Tr1 is electrically connected to the photodiode PD. The other of the source and drain of the gain-switching transistor Tr2 is electrically connected to the capacitive element Cs. The impurity region X is electrically connected to the gate of the amplification transistor Tr4. One of the source and drain of the amplification transistor Tr4 is electrically connected to one of the source and drain of the address transistor Tr5.

The gain-switching transistor Tr2 may be referred to as the first transistor. The amplification transistor Tr4 may be referred to as the second transistor. The reset transistor Tr3 may be referred to as the third transistor. The forwarding transistor Tr1 may be referred to as the fourth transistor. The technologies described above in the embodiments are applicable to the circuit example illustrated in FIG. 21 without inconsistency. In this case, the above description holds when “the gain-switching transistor 29 as the first transistor” is replaced with “the gain-switching transistor Tr2 as the first transistor”, “the amplification transistor 22 as the second transistor” is replaced with “the amplification transistor Tr4 as the second transistor”, “the reset transistor 26 as the third transistor” is replaced with “the reset transistor Tr3 as the third transistor”, and “the forwarding transistor 31 as the fourth transistor” is replaced with “the forwarding transistor Tr1 as the fourth transistor”. For example, the thickness of the first gate-insulating film of the first transistor is greater than the thickness of the second gate-insulating film of the second transistor.

Circuit Example Illustrated in FIG. 22

FIG. 22 is FIG. 1 of the specification of U.S. Unexamined Patent Application Publication No. 2009/256940 in which the numerical value of each reference sign is changed through addition of 700 and a reference sign X is added. Specifically, FIG. 22 illustrates a photodiode 812 as a photoelectric converter that is a silicon photodiode, a forwarding transistor 810, a reset transistor 820, a gain-switching transistor 850, a capacitive element Cl, an amplification transistor 830, and an address transistor 840.

The impurity region X serves as one of the source and drain of the forwarding transistor 810, one of the source and drain of the reset transistor 820, and one of the source and drain of the gain-switching transistor 850. The other of the source and drain of the forwarding transistor 810 is electrically connected to the photodiode 812. The other of the source and drain of the gain-switching transistor 850 is electrically connected to the capacitive element Cl. The impurity region X is electrically connected to the gate of the amplification transistor 830. One of the source and drain of the amplification transistor 830 is electrically connected to one of the source and drain of the address transistor 840.

The gain-switching transistor 850 may be referred to as the first transistor. The amplification transistor 830 may be referred to as the second transistor. The reset transistor 820 may be referred to as the third transistor. The forwarding transistor 810 may be referred to as the fourth transistor. The technologies described above in the embodiments are applicable to the circuit example illustrated in FIG. 22 without inconsistency. In this case, the above description holds when “the gain-switching transistor 29 as the first transistor” is replaced with “the gain-switching transistor 850 as the first transistor”, “the amplification transistor 22 as the second transistor” is replaced with “the amplification transistor 830 as the second transistor”, “the reset transistor 26 as the third transistor” is replaced with “the reset transistor 820 as the third transistor”, and “the forwarding transistor 31 as the fourth transistor” is replaced with “the forwarding transistor 810 as the fourth transistor”. For example, the thickness of the first gate-insulating film of the first transistor is greater than the thickness of the second gate-insulating film of the second transistor.

The embodiments and modifications of an imaging device according to the present disclosure are described above, but the present disclosure is not limited to the embodiments and modifications. The embodiments and modifications provided with various kinds of changes that could be thought of by the skilled person in the art, and any other form configured by combining some constituent components in the embodiments and modifications are included in the scope of the present disclosure without departing from the gist of the present disclosure.

According to the embodiments and modifications of the present disclosure, increase of the charge storage capacitance (FD capacitance) can be reduced, and thus an imaging device capable of performing imaging at high sensitivity is provided. The above-described amplification transistors, address transistors, reset transistors, and seizure prevention transistors may be each an N-channel MOSFET or a P-channel MOSFET. This also applies to other transistors. In a case in which each transistor is a P-channel MOSFET, first conduction type impurities are p-type impurities, and second conduction type impurities are n-type impurities. Not all of the transistors need to be unified to any of an N-channel MOSFET and a P-channel MOSFET. In a case in which each transistor in pixels is an N-channel MOSFET and electrons are used as signal electric charge, dispositions of the source and drain of each transistor may be interchanged with each other.

According to the present disclosure, an imaging device capable of reducing the charge storage capacitance (FD capacitance) and performing imaging at high sensitivity is provided. The imaging device of the present disclosure is useful for an image sensor, a digital camera, and the like. The imaging device of the present disclosure is applicable to a medical camera, a robot camera, a security camera, a camera mounted and used on a vehicle, and the like.

What is claimed is:

1. An imaging device comprising:
a semiconductor substrate;
an impurity region that is located in the semiconductor substrate and that holds electric charge generated through photoelectric conversion;
a first transistor including a first source, a first drain, a first gate, and a first gate-insulating film, one of the first source and the first drain including the impurity region, the first gate being electrically connected to the impurity region, the first gate-insulating film being located between the first gate and the semiconductor substrate; and
a second transistor including a second gate and a second gate-insulating film, the second gate being electrically connected to the impurity region, the second gate-insulating film being located between the second gate and the semiconductor substrate, wherein
a thickness of the first gate-insulating film is greater than a thickness of the second gate-insulating film.

2. The imaging device according to claim 1, further comprising a photoelectric converter that is located above the semiconductor substrate and that generates the electric charge through photoelectric conversion.

3. The imaging device according to claim 1, further comprising a third transistor including a third source, a third drain, a third gate, and a third gate-insulating film, one of the third source and the third drain including the impurity region, the third gate-insulating film being located between the third gate and the semiconductor substrate.

4. The imaging device according to claim 3, wherein a thickness of the third gate-insulating film is greater than the thickness of the second gate-insulating film.

5. The imaging device according to claim 1, wherein a width of the first gate is less than a width of the second gate.

6. The imaging device according to claim 1, wherein an area of the first gate is less than an area of the second gate in a plan view.

7. The imaging device according to claim 1, wherein a ratio of a length of the first gate relative to a width of the first gate is greater than a ratio of a length of the second gate relative to a width of the second gate.

8. The imaging device according to claim 1, further comprising an insulating layer, wherein
the insulating layer includes a first part and a second part, the first part including the first gate-insulating film, the second part including the second gate-insulating film,
a thickness of the first part is greater than a thickness of the second part, and
when a shortest line segment connecting the first gate and the second gate in a plan view is defined as a specific line segment and a middle point of the specific line segment is defined as a specific point, the specific point is located on the first part in the plan view.

9. The imaging device according to claim 1, further comprising:
an insulating layer; and
a wire electrically connected to the first gate, wherein
the insulating layer includes a first part and a second part, the first part including the first gate-insulating film, the second part including the second gate-insulating film,
a thickness of the first part is greater than a thickness of the second part, and
when a region in which the semiconductor substrate, the first part, and the wire are arranged in the stated order in a thickness direction of the semiconductor substrate is defined as a specific region, the specific region extends from inside of the first gate to outside of the first gate in a plan view.

10. The imaging device according to claim 1, wherein the second transistor is an amplification transistor.

11. The imaging device according to claim 3, wherein the thickness of the first gate-insulating film is greater than a thickness of the third gate-insulating film.

12. The imaging device according to claim 3, wherein the thickness of the second gate-insulating film is equal to a thickness of the third gate-insulating film.

13. The imaging device according to claim 2, wherein the photoelectric converter is constantly electrically connected to the impurity region.

14. The imaging device according to claim 2, wherein no switch element is located between the photoelectric converter and the impurity region.
